(19) United States
(12) Patent Application Publication
(10) Pub. No.: US 2025/0391443 A1
(43) Pub. Date: Dec. 25, 2025

(54) SEMICONDUCTOR DEVICE AND METHOD OF MANUFACTURING THE SAME

(71) Applicant: Kioxia Corporation, Tokyo (JP)

(72) Inventor: Hisashi KATO, Yokkaichi Mie (JP)

(21) Appl. No.: 19/069,096

(22) Filed: Mar. 3, 2025

(30) Foreign Application Priority Data
Jun. 25, 2024 (JP) 2024-102419

(51) Int. Cl. G11C 5/06; H01L 23/00; H10B 43/20

(52) U.S. Cl. CPC G11C 5/063; H01L 24/08; H10B 43/20; H01L 2224/08235

(57) ABSTRACT

A semiconductor device includes a first insulating film, a second insulating film on the first insulating film, a first electrode layer on the second insulating film, second electrode layers above the first electrode layer and spaced apart from each other in a first direction, a third insulating film on each of the first electrode layer and the second electrode layers, a fourth insulating film on the third insulating film, a third electrode layer on the fourth insulating film, fourth electrode layers above the third electrode layer and spaced apart from each other in the first direction, a first plug electrically connected to the first electrode layer, a second plug electrically connected to any one of the second electrode layers, a third plug electrically connected to the third electrode layer, and a fourth plug electrically connected to any one of the fourth electrode layers.

### CROSS-REFERENCE TO RELATED APPLICATION

This application is based upon and claims the benefit of priority from Japanese Patent Application No. 2024-102419, filed Jun. 25, 2024, the entire contents of which are incorporated herein by reference.

### FIELD

Embodiments described herein relate generally to a semiconductor device and a method of manufacturing the same.

### BACKGROUND

In a three-dimensional semiconductor memory, a contact plug for a word line is formed to penetrate other word lines. In such a case, when a three-dimensional semiconductor memory is manufactured, it can be difficult to form a contact plug due to an insulating film on the uppermost word line or an insulating film between adjacent word lines. For example, when the film thickness of the insulating film on the uppermost word line is larger than that of the insulating film between adjacent word lines, a step of forming the contact plug may become complicated due to the difference in film thickness between the insulating films.

### BRIEF DESCRIPTION OF THE DRAWINGS

FIG. 1 is a cross-sectional view showing a structure of a semiconductor device according to a first embodiment.

FIG. 2 is an enlarged cross-sectional view showing the structure of the semiconductor device according to the first embodiment.

FIG. 3 is a cross-sectional view (1/2) showing a method of manufacturing the semiconductor device according to the first embodiment.

FIG. 4 is a cross-sectional view (2/2) showing the method of manufacturing the semiconductor device according to the first embodiment.

FIG. 5 is a cross-sectional view showing a structure of a semiconductor device according to a comparative example.

FIG. 6 is a cross-sectional view showing the structure of the semiconductor device according to the first embodiment.

FIG. 7 is a cross-sectional view (1/16) showing a method of manufacturing the semiconductor device according to the comparative example.

FIG. 8 is a cross-sectional view (2/16) showing the method of manufacturing the semiconductor device according to the comparative example.

FIG. 9 is a cross-sectional view (3/16) showing the method of manufacturing the semiconductor device according to the comparative example.

FIG. 10 is a cross-sectional view (4/16) showing the method of manufacturing the semiconductor device according to the comparative example.

FIG. 11 is a cross-sectional view (5/16) showing the method of manufacturing the semiconductor device according to the comparative example.

FIG. 12 is a cross-sectional view (6/16) showing the method of manufacturing the semiconductor device according to the comparative example.

FIG. 13 is a cross-sectional view (7/16) showing the method of manufacturing the semiconductor device according to the comparative example.

FIG. 14 is a cross-sectional view (8/16) showing the method of manufacturing the semiconductor device according to the comparative example.

FIG. 15 is a cross-sectional view (9/16) showing the method of manufacturing the semiconductor device according to the comparative example.

FIG. 16 is a cross-sectional view (10/16) showing the method of manufacturing the semiconductor device according to the comparative example.

FIG. 17 is a cross-sectional view (11/16) showing the method of manufacturing the semiconductor device according to the comparative example.

FIG. 18 is a cross-sectional view (12/16) showing the method of manufacturing the semiconductor device according to the comparative example.

FIG. 19 is a cross-sectional view (13/16) showing the method of manufacturing the semiconductor device according to the comparative example.

FIG. 20 is a cross-sectional view (14/16) showing the method of manufacturing the semiconductor device according to the comparative example.

FIG. 21 is a cross-sectional view (15/16) showing the method of manufacturing the semiconductor device according to the comparative example.

FIG. 22 is a cross-sectional view (16/16) showing the method of manufacturing the semiconductor device according to the comparative example.

FIG. 23 is a cross-sectional view (1/18) showing the method of manufacturing the semiconductor device according to the first embodiment.

FIG. 24 is a cross-sectional view (2/18) showing the method of manufacturing the semiconductor device according to the first embodiment.

FIG. 25 is a cross-sectional view (3/18) showing the method of manufacturing the semiconductor device according to the first embodiment.

FIG. 26 is a cross-sectional view (4/18) showing the method of manufacturing the semiconductor device according to the first embodiment.

FIG. 27 is a cross-sectional view (5/18) showing the method of manufacturing the semiconductor device according to the first embodiment.

FIG. 28 is a cross-sectional view (6/18) showing the method of manufacturing the semiconductor device according to the first embodiment.

FIG. 29 is a cross-sectional view (7/18) showing the method of manufacturing the semiconductor device according to the first embodiment.

FIG. 30 is a cross-sectional view (8/18) showing the method of manufacturing the semiconductor device according to the first embodiment.

FIG. 31 is a cross-sectional view (9/18) showing the method of manufacturing the semiconductor device according to the first embodiment.

FIG. 32 is a cross-sectional view (10/18) showing the method of manufacturing the semiconductor device according to the first embodiment.

FIG. 33 is a cross-sectional view (11/18) showing the method of manufacturing the semiconductor device according to the first embodiment.

FIG. 34 is a cross-sectional view (12/18) showing the method of manufacturing the semiconductor device according to the first embodiment.

FIG. 35 is a cross-sectional view (13/18) showing the method of manufacturing the semiconductor device according to the first embodiment.

FIG. 36 is a cross-sectional view (14/18) showing the method of manufacturing the semiconductor device according to the first embodiment.

FIG. 37 is a cross-sectional view (15/18) showing the method of manufacturing the semiconductor device according to the first embodiment.

FIG. 38 is a cross-sectional view (16/18) showing the method of manufacturing the semiconductor device according to the first embodiment.

FIG. 39 is a cross-sectional view (17/18) showing the method of manufacturing the semiconductor device according to the first embodiment.

FIG. 40 is a cross-sectional view (18/18) showing the method of manufacturing the semiconductor device according to the first embodiment.

FIG. 41 is a cross-sectional view (1/4) showing a method of manufacturing a semiconductor device according to a second embodiment.

FIG. 42 is a cross-sectional view (2/4) showing the method of manufacturing the semiconductor device according to the second embodiment.

FIG. 43 is a cross-sectional view (3/4) showing the method of manufacturing the semiconductor device according to the second embodiment.

FIG. 44 is a cross-sectional view (4/4) showing the method of manufacturing the semiconductor device according to the second embodiment.

FIG. 45 is a cross-sectional view showing a structure of a semiconductor device according to a third embodiment.

FIG. 46 is a cross-sectional view showing a structure of a semiconductor device according to a fourth embodiment.

FIG. 47 is a cross-sectional view showing a structure of a semiconductor device according to a fifth embodiment.

FIG. 48 is a cross-sectional view (1/2) showing a method of manufacturing the semiconductor device according to the fifth embodiment.

FIG. 49 is a cross-sectional view (2/2) showing the method of manufacturing the semiconductor device according to the fifth embodiment.

FIG. 50 is a cross-sectional view showing a structure of a semiconductor device according to a modification example of the fifth embodiment.

FIG. 51 is a cross-sectional view showing a structure of a semiconductor device according to a sixth embodiment.

FIG. 52 is a cross-sectional view (1/2) showing a method of manufacturing the semiconductor device according to the sixth embodiment.

FIG. 53 is a cross-sectional view (2/2) showing the method of manufacturing the semiconductor device according to the sixth embodiment.

FIG. 54 is a cross-sectional view showing a structure of a semiconductor device according to a modification example of the sixth embodiment.

### DETAILED DESCRIPTION

Embodiments provide a semiconductor device and a method of manufacturing the same which are capable of preferably forming a contact plug.

In general, according to one embodiment, a semiconductor device comprises a first insulating film; a second insulating film on the first insulating film; a first electrode layer on the second insulating film; a plurality of second electrode layers above the first electrode layer and spaced apart from each other in a first direction; a third insulating film on each of the first electrode layer and the plurality of second electrode layers; a fourth insulating film on the third insulating film; a third electrode layer on the fourth insulating film; a plurality of fourth electrode layers above the third electrode layer and spaced apart from each other in the first direction; a first plug extending in the first direction and electrically connected to the first electrode layer; a second plug extending in the first direction and electrically connected to any one of the second electrode layers; a third plug extending in the first direction and electrically connected to the third electrode layer; and a fourth plug extending in the first direction and electrically connected to any one of the fourth electrode layers. The fourth plug includes: a first portion penetrating the second insulating film, the first electrode layer, the second electrode layers, and the third insulating film, and a second portion disposed on the first portion and penetrating the fourth insulating film and the third electrode layer. A diameter of the fourth plug changes discontinuously along the first direction at a boundary between the first and second portions. The third plug includes: a third portion penetrating the second insulating film, the first electrode layer, the second electrode layers, and the third insulating film, and a fourth portion disposed on the third portion and penetrating the fourth insulating film. A diameter of the third plug changes discontinuously along the first direction at a boundary between the third and fourth portions.

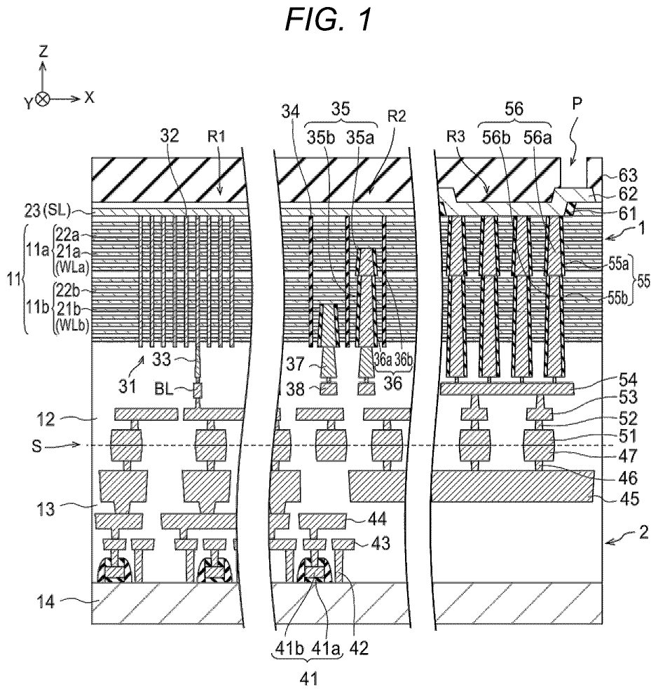

Hereinafter, several embodiments of the present disclosure will be described with reference to the drawings. In FIG. 1 to FIG. 54, the same components are denoted by the same reference numerals, and duplicated descriptions will be omitted.

### First Embodiment

FIG. 1 is a cross-sectional view showing a structure of a semiconductor device according to a first embodiment.

As shown in FIG. 1, the semiconductor device according to this embodiment includes an array chip 1 and a circuit chip 2 that are bonded together. In FIG. 1, the array chip 1 is disposed on the circuit chip 2. A symbol “S” represents a bonding surface between the array chip 1 and the circuit chip 2. The semiconductor device according to this embodiment is, for example, a three-dimensional semiconductor memory.

The array chip 1 includes a stacked film 11 including a plurality of electrode layers, and an interlayer insulating film 12 provided under the stacked film 11. The interlayer insulating film 12 is, for example, a stacked insulating film including a SiO2 film (silicon oxide film) and other insulating films. The interlayer insulating film 12 in this embodiment is provided not only above the stacked film 11, but also under the stacked film 11.

The circuit chip 2 includes an interlayer insulating film 13 disposed under the interlayer insulating film 12, and a substrate 14 disposed under the interlayer insulating film 13. The interlayer insulating film 13 is, for example, a stacked insulating film including a SiO2 film and other insulating films. The substrate 14 is, for example, a semiconductor substrate such as a Si (silicon) substrate.

An X direction, a Y direction, and a Z direction shown in FIG. 1 intersect each other. Specifically, FIG. 1 shows the X direction and Y direction parallel to the surface of the substrate 14 and perpendicular to each other, and the Z direction perpendicular to the surface of the substrate 14. In this specification, a +Z direction is treated as an upward direction, and a −Z direction is treated as a downward direction. The −Z direction may or may not coincide with the direction of gravity. The Z direction is an example of a first direction.

As shown in FIG. 1, the stacked film 11 includes a stacked film 11a including a plurality of electrode layers 21a and a plurality of insulating films 22a alternately in the Z direction, and a stacked film 11b including a plurality of electrode layers 21b and a plurality of insulating films 22b alternately in the Z direction. These electrode layers 21a and 21b in the stacked films 11a and 11b are spaced apart from each other in the Z direction. In FIG. 1, the stacked film 11a is provided above the stacked film 11b. The array chip 1 further includes a wiring layer 23 provided in the interlayer insulating film 12 above the stacked films 11a and 11b.

As shown in FIG. 1, the stacked film 11 includes regions R1, R2, and R3. The electrode layers 21a and 21b and the insulating films 22a and 22b in this embodiment are provided across the regions R1, R2, and R3, and the wiring layer 23 in this embodiment is provided above the regions R1, R2, and R3.

The region R1 forms a memory cell array 31 together with the wiring layer 23 and the like. In the memory cell array 31, the electrode layers 21a and 21b function as word lines WLa and WLb, respectively, and the wiring layer 23 functions as a source line SL. The memory cell array 31 further includes a source-side selection line and a drain-side selection line (not shown) in the stacked film 11. FIG. 1 further shows a plurality of columnar portions 32 penetrating the region R1 in the Z direction. These columnar portions 32 form a plurality of memory cells together with the electrode layers 21a and 21b. The columnar portions 32 are electrically connected to the source line SL and is electrically connected to a bit line BL via a contact plug 33.

In the region R2, the array chip 1 includes a plurality of beam portions 34, a plurality of contact plugs 36, and the like. Each beam portion 34 penetrates the region R2 in the Z direction. Each contact plug 36 is provided in the region R2 via a spacer insulating film 35, and is electrically connected to any one of the electrode layers 21a in the stacked film 11a or any one of the electrode layers 21b in the stacked film 11b. As shown in FIG. 1, the contact plug 36 electrically connected to the electrode layer 21a includes a plug 36a provided in the stacked film 11a and a plug 36b provided in the stacked film 11b and below the plug 36a, and the contact plug 36 electrically connected to the electrode layer 21b includes a plug 36b provided in the stacked film 11b. The side surface of each plug 36a is surrounded by an insulating film 35a in the spacer insulating film 35, and the side surface of each plug 36b is surrounded by an insulating film 35b in the spacer insulating film 35. The array chip 1 further includes a plurality of contact plugs 37 and the like below the region R2. Each contact plug 37 is provided below the corresponding contact plug 36, and electrically connects the contact plug 36 to a word wiring layer 38.

In the region R3, the array chip 1 includes a plurality of via plugs 56 and the like. Details of these via plugs 56 will be described later.

The circuit chip 2 further includes a plurality of transistors 41, a plurality of contact plugs 42, a wiring layer 43, a wiring layer 44, a wiring layer 45, a plurality of via plugs 46, and a plurality of metal pads 47.

Each transistor 41 includes a gate insulating film 41a and a gate electrode 41b provided in this order on the substrate 14, and a source region and a drain region (not shown) provided in the substrate 14. Each contact plug 42 is provided on the gate electrode 41b, the source region, or the drain region of the corresponding transistor 41. The wiring layer 43 includes a plurality of wirings and is provided on the contact plug 42. The wiring layer 44 includes a plurality of wirings and is provided on the wiring layer 43. The wiring layer 45 includes a plurality of wirings and is provided on the wiring layer 44. The via plug 46 is provided on the wiring layer 45. The metal pad 47 is provided on the via plug 46. Each metal pad 47 is, for example, a metal layer including a Cu (copper) layer. The circuit chip 2 includes a logic circuit that controls the operation of the array chip 1. This logic circuit is configured with the transistors 41 and the like, and is electrically connected to the metal pads 47.

The array chip 1 further includes a plurality of metal pads 51, a plurality of via plugs 52, a wiring layer 53, a wiring layer 54, a plurality of spacer insulating films 55, and the plurality of via plugs 56 mentioned above.

The metal pads 51 are provided on the metal pads 47. Each metal pad 51 is, for example, a metal layer including a Cu layer. The above-mentioned logic circuit is electrically connected to the memory cell array 31 via the metal pads 47 and 51 and the like, and controls the operation of the memory cell array 31 via the metal pads 47 and 51 and the like. The via plugs 52 are provided on the metal pads 51. The wiring layer 53 includes a plurality of wirings and is provided on the via plugs 52. The wiring layer 54 includes a plurality of wirings and is provided on the wiring layer 53. The above-mentioned bit lines BL are provided in the wiring layer 54. Each via plug 56 is disposed on the wiring layer 54, is provided in the region R3 via the spacer insulating film 55, and penetrates the region R3 in the Z direction. Each via plug 56 includes a plug 56a provided in the stacked film 11a and a plug 56b provided in the stacked film 11b below the plug 56a. The side surface of each plug 56a is surrounded by the insulating film 55a in the spacer insulating film 55, and the side surface of each plug 56b is surrounded by the insulating film 55b in the spacer insulating film 55.

The array chip 1 further includes an insulating film 61, a metal pad 62, and a passivation insulating film 63.

The insulating film 61 is provided on the side surfaces of the interlayer insulating film 12 and the wiring layer 23 in a recess portion provided in the interlayer insulating film 12. The metal pad 62 is provided on the upper surfaces of the interlayer insulating film 12 and the via plug 56 and on the side surface of the insulating film 61 in the recess portion of the interlayer insulating film 12, and is provided on the upper surfaces of the interlayer insulating film 12 and the insulating film 61 outside the recess portion of the interlayer insulating film 12. The metal pad 62 is, for example, a metal layer including a Cu layer, and functions as an external connection pad (i.e., a bonding pad) of the semiconductor device according to this embodiment. The passivation insulating film 63 is provided on the metal pad 62 and the interlayer insulating film 12, and has an opening P that exposes the upper surface of the metal pad 62. The metal pad 62 can be electrically connected to a mounting board or other devices via the opening P using a bonding wire, a solder ball, a metal bump, or the like.

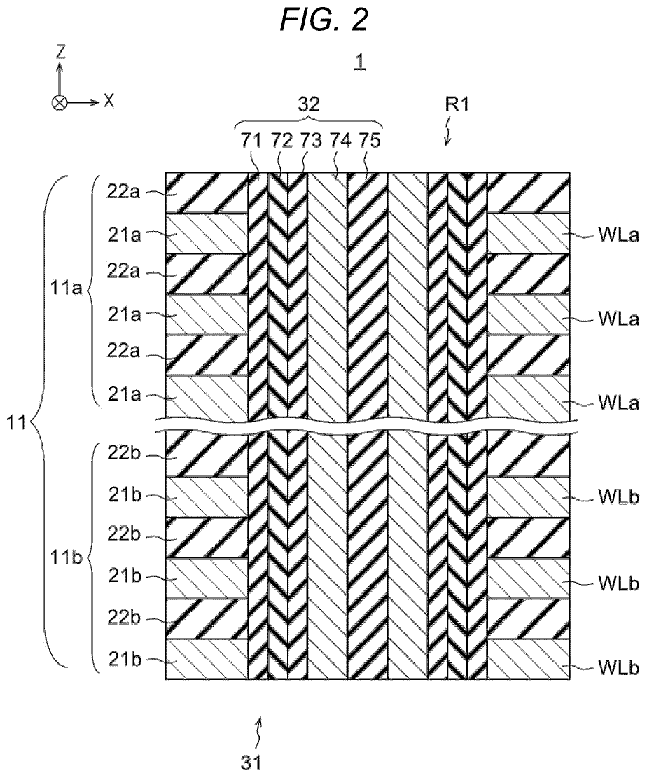

FIG. 2 is an enlarged cross-sectional view showing the structure of the semiconductor device according to the first embodiment.

FIG. 2 shows the region R1 of the stacked film 11 shown in FIG. 1. The stacked film 11 includes the stacked film 11a including the plurality of electrode layers 21a and the plurality of insulating films 22a alternately in the Z direction, and the stacked film 11b including the plurality of electrode layers 21b and the plurality of insulating films 22b alternately in the Z direction. As described above, the electrode layers 21a and 21b function as the word lines WLa and WLb, respectively. Each of the electrode layers 21a and 21b is, for example, a metal layer including a W layer. Each of the insulating films 22a and 22b is, for example, a SiO2 film.

FIG. 2 further shows one of the plurality of columnar portions 32 shown in FIG. 1. As shown in FIG. 2, each columnar portion 32 includes a block insulating film 71, a charge storage layer 72, a tunnel insulating film 73, a channel semiconductor layer 74, and a core insulating film 75, which are provided in this order in the stacked film 11. The block insulating film 71 is, for example, a SiO2 film. The charge storage layer 72 is, for example, a SiN film (silicon nitride film). The tunnel insulating film 73 is, for example, a SiO2 film. The channel semiconductor layer 74 is, for example, a polysilicon layer. The core insulating film 75 is, for example, a SiO2 film.

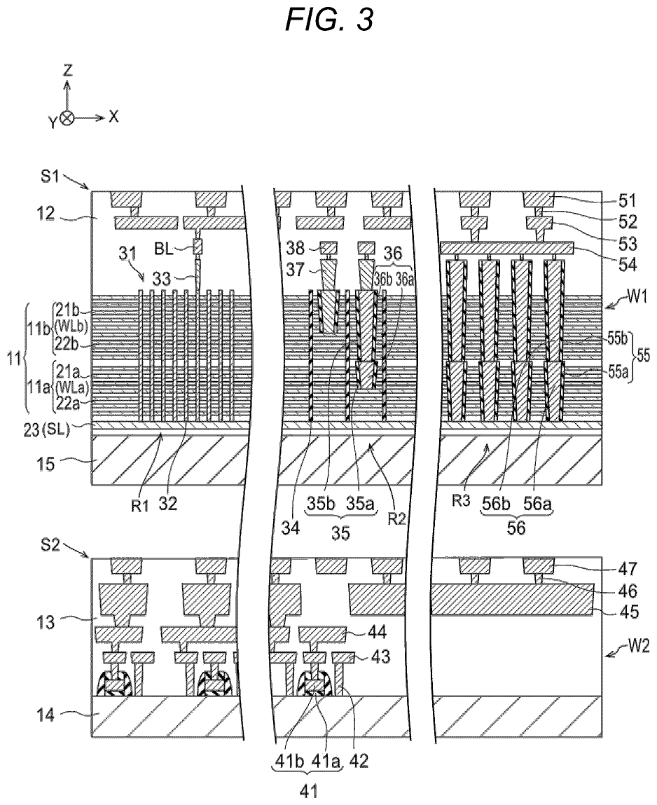

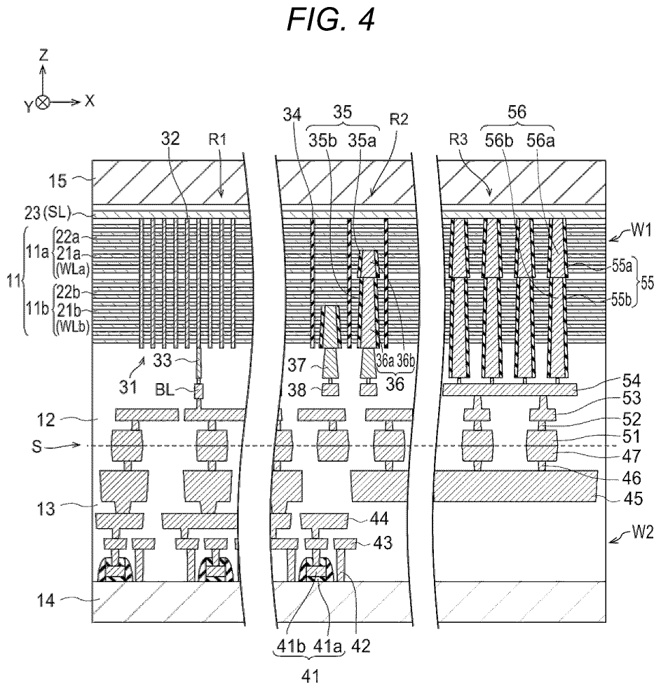

FIGS. 3 and 4 are cross-sectional views showing a method of manufacturing the semiconductor device according to the first embodiment.

FIG. 3 shows an array wafer W1 including a plurality of array chips 1 and a circuit wafer W2 including a plurality of circuit chips 2. The orientation of the array wafer W1 in FIG. 3 is opposite to the orientation of the array chip 1 in FIG. 1. In this embodiment, a semiconductor device is manufactured by bonding the array wafer W1 and the circuit wafer W2 together. FIG. 3 shows the array wafer W1 before its orientation is reversed for bonding, and FIG. 1 shows the array chip 1 after its orientation is reversed for bonding and then bonding and dicing are performed.

FIG. 3 further shows an upper surface S1 of the array wafer W1 and an upper surface S2 of the circuit wafer W2. The array wafer W1 includes a substrate 15 disposed under the interlayer insulating film 12. The substrate 15 is, for example, a semiconductor substrate such as a Si substrate.

In this embodiment, first, as shown in FIG. 3, the stacked film 11, the interlayer insulating film 12, the wiring layer 23, the memory cell array 31, the columnar portion 32, the contact plug 36, the contact plug 37, the metal pad 51, the via plug 56 and the like are formed on the substrate 15 of the array wafer W1, and the interlayer insulating film 13, the transistor 41, the contact plug 42, the metal pad 47, and the like are formed on the substrate 14 of the circuit wafer W2. Next, as shown in FIG. 4, the array wafer W1 and the circuit wafer W2 are bonded together by mechanical pressure so that the upper surface S1 and the upper surface S2 face each other. Thereby, the interlayer insulating film 12 and the interlayer insulating film 13 are bonded together. Next, the array wafer W1 and the circuit wafer W2 are annealed. Thereby, the metal pad 51 and the metal pad 47 are bonded together. In this manner, the substrate 15 and the substrate 14 are bonded together so that the interlayer insulating films 12 and 13 are sandwiched therebetween.

Thereafter, the substrate 14 is thinned by chemical mechanical polishing (CMP), the substrate 15 is removed by CMP, and the array wafer W1 and the circuit wafer W2 are cut into a plurality of chips. In this manner, the semiconductor device according to this embodiment is manufactured (FIG. 1). The insulating film 61, the metal pad 62, and the passivation insulating film 63 shown in FIG. 1 are formed above the stacked film 11 and the wiring layer 23 after the substrate 14 is thinned and the substrate 15 is removed.

FIG. 1 shows a boundary surface between the interlayer insulating film 12 and the interlayer insulating film 13, and a boundary surface between the metal pad 51 and the metal pad 47, but these boundary surfaces are generally not visible after the above-mentioned annealing. However, the positions of these boundary surfaces can be estimated by detecting, for example, an inclination of the side surface of the metal pad 51 or the side surface of the metal pad 47, or a positional deviation between the side surface of the metal pad 51 and the side surface of the metal pad 47.

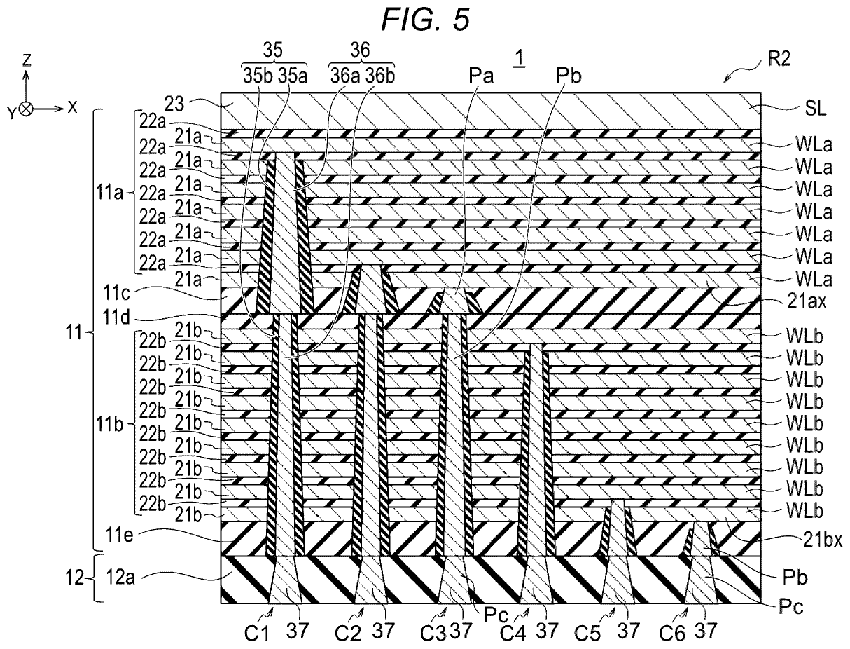

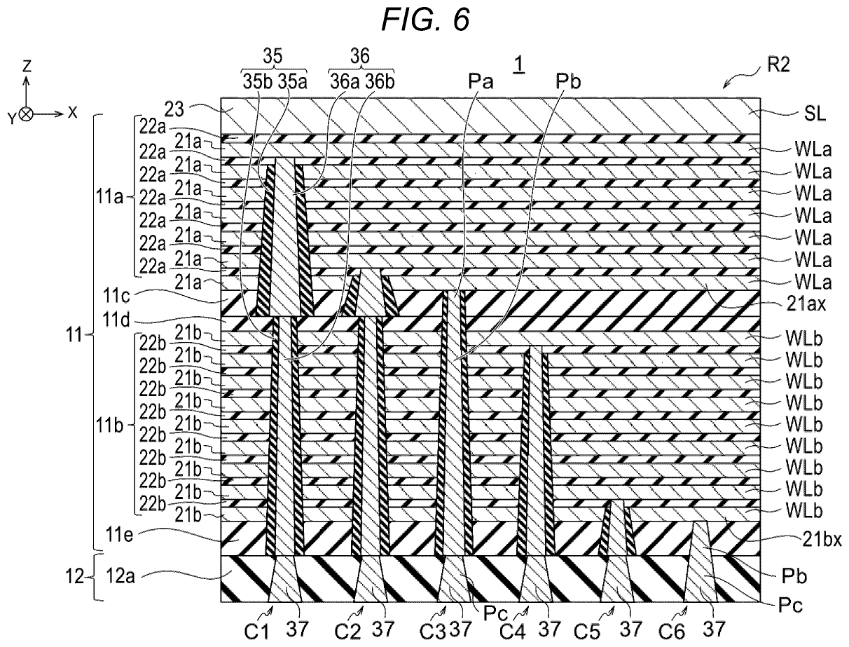

Next, the structure of the semiconductor device according to this embodiment will be described in comparison with a comparative example with reference to FIGS. 5 and 6.

FIG. 5 is a cross-sectional view showing a structure of a semiconductor device according to the comparative example.

The semiconductor device according to this comparative example (FIG. 5) has a structure that is substantially the same as that of the semiconductor device according to the first embodiment (FIG. 1). Thus, the semiconductor device according to this comparative example will be described as a continuation of the above description of the semiconductor device according to the first embodiment, except for differences between the first embodiment and this comparative example. For example, this comparative example will be described using the same reference numerals as those in the first embodiment. The differences between the first embodiment and this comparative example will be described later.

FIG. 5 shows the region R2 of the stacked film 11. FIG. 5 further shows an insulating film 12a, which is a portion of the interlayer insulating film 12, and the wiring layer 23 corresponding to the source line SL. The stacked film 11 according to this comparative example includes an insulating film 11e, a stacked film 11b, an insulating film 11d, an insulating film 11c, and a stacked film 11a, which are provided in this order on the insulating film 12a. As described above, the stacked film 11b includes a plurality of electrode layers 21b corresponding to the word lines WLb and a plurality of insulating films 22b alternately in the Z direction, and the stacked film 11a includes a plurality of electrode layers 21a corresponding to the word lines WLa and a plurality of insulating films 22a alternately in the Z direction. The insulating films 11c and 11d provided between the stacked film 11a and the stacked film 11b are referred to as joint insulating films, and the insulating film 11e provided under the stacked films 11a and 11b is referred to as an external insulating film. The insulating films 11c, 11d, 11e, 12a, 22a, and 22b in this comparative example are, for example, SiO2 films.

In this comparative example, the film thicknesses of the electrode layers 21a and 21b in the stacked film 11 are all set to the same value, and the film thicknesses of the insulating films 22a and 22b in the stacked film 11 are all set to the same value. In this comparative example, the total film thickness of the insulating films 11c and 11d (i.e., the film thickness of the joint insulating film) is set to be larger than the film thicknesses of the insulating films 22a and 22b. Further, in this comparative example, the film thickness of the insulating film 11c and the film thickness of the insulating film 11e are set to be larger than the film thicknesses of the insulating films 22a and 22b.

FIG. 5 further shows an electrode layer 21ax and an electrode layer 21bx. The electrode layer 21ax is the lowermost electrode layer 21a among the plurality of electrode layers 21a in the stacked film 11a. The electrode layer 21bx is the lowermost electrode layer 21b among the plurality of electrode layers 21b in the stacked film 11b. Further details of the electrode layers 21ax and 21bx will be described later.

FIG. 5 further shows a plurality of contact plugs 37 provided in the insulating film 12a and a plurality of contact plugs 36 provided in the stacked film 11. Each contact plug 36 includes plugs 36a and 36b, or includes only the plug 36b. In FIG. 5, each plug 36b is provided in the insulating film 11e, or in the insulating film 11e and the stacked film 11b, or in the insulating film 11e, the stacked film 11b, and the insulating film 11d, and each plug 36a is provided in the insulating film 11c, or in the insulating film 11c and the stacked film 11a.

In the following description, a plug including one contact plug 36 and one contact plug 37 provided under the contact plug 36 is referred to as a plug C. FIG. 5 shows six plugs C1 to C6 as examples of the plug C. The plug C may include not only the contact plugs 36 and 37, but also only the contact plug 37, as will be described later.

The plug C1 includes plugs 36a and 36b and the contact plug 37, and is electrically connected to one electrode layer 21a other than the electrode layer 21ax. This is the same for the plug C2. In addition, the plug C3 includes the plugs 36a and 36b and the contact plug 37, and is electrically connected to the electrode layer 21ax.

The plug C4 includes the plug 36b and the contact plug 37, and is electrically connected to one electrode layer 21b other than the electrode layer 21bx. This is the same for the plug C5. Furthermore, the plug C6 includes the plug 36b and the contact plug 37, and is electrically connected to the electrode layer 21bx.

Symbols Pa, Pb, and Pc shown in FIG. 5 represent portions in each plug C. The symbol Pa represents portions in the stacked film 11a and the insulating film 11c of each plug C. The symbol Pb represents portions in the stacked film 11b, the insulating film 11d, and the insulating film 11e of each plug C. The symbol Pc represents portions in the insulating film 12a of each plug C. Thus, the portions Pa, Pb, and Pc of each plug C in this comparative example correspond to the plug 36a, the plug 36b, and the contact plug 37 of each plug C, respectively. Each of the plugs C1 to C3 includes the portions Pa, Pb, and Pc, and is electrically connected to any of the electrode layers 21a in the stacked film 11a. Each of the plugs C4 to C6 includes only the portions Pb and Pc, and is electrically connected to any of the electrode layers 21b in the stacked film 11b. Further details of the portions Pa, Pb, and Pc will be described later.

In this comparative example, when manufacturing a semiconductor device, it is difficult to preferably form the plugs C1 to C6 due to the insulating films 11c, 11d, 11e, 12a, 22a, and 22b, and the like. Specifically, it is difficult to preferably form a contact hole for the contact plug 36. Further details of this problem will be described later.

FIG. 6 is a cross-sectional view showing the structure of the semiconductor device according to the first embodiment.

The semiconductor device according to this embodiment shown in FIG. 6 has a structure that is substantially the same as that of the semiconductor device according to the comparative example shown in FIG. 5. In the following description of FIG. 6, the description of the common points between FIG. 5 and FIG. 6 will be omitted to some extent, and the description will be given focusing on the differences between FIG. 5 and FIG. 6.

FIG. 6 shows the region R2 of the stacked film 11, as in FIG. 5. The stacked film 11 according to this embodiment also includes an insulating film 11e, a stacked film 11b, an insulating film 11d, an insulating film 11c, and a stacked film 11a, which are provided in this order on the insulating film 12a. The stacked film 11b includes a plurality of electrode layers 21b corresponding to the word lines WLb and a plurality of insulating films 22b alternately in the Z direction, and the stacked film 11a includes a plurality of electrode layers 21a corresponding to the word lines WLa and a plurality of insulating films 22a alternately in the Z direction. In this embodiment, the insulating films 11c, 11d, 11e, 12a, 22a, and 22b are, for example, SiO2 films. The insulating films 12a and 11e are examples of first and second insulating films, respectively. The insulating films 11d and 11c are examples of third and fourth insulating films, respectively. The insulating films 22b and 22a are examples of fifth and sixth insulating films, respectively.

In this embodiment, the film thicknesses of the electrode layers 21a and 21b in the stacked film 11 are all set to the same value, and the film thicknesses of the insulating films 22a and 22b in the stacked film 11 are all set to the same value. In this embodiment, the total film thickness (i.e., the film thickness of the joint insulating film) of the insulating films 11c and 11d is further set to be larger than the film thicknesses of the insulating films 22a and 22b. In this embodiment, the film thickness of the insulating film 11c and the film thickness of the insulating film 11e are further set to be larger than the film thicknesses of the insulating films 22a and 22b. The above is the same as in the comparative example. The stacked film 11 may include the electrode layer 21a or the electrode layer 21b having a film thickness different from those of the other electrode layers 21a and 21b. The stacked film 11 may also include an insulating film 22a or an insulating film 22b having a film thickness different from those of the other insulating films 22a and 22b.

FIG. 6 further shows the electrode layer 21ax and the electrode layer 21bx as in FIG. 5. The electrode layer 21ax is the lowermost electrode layer 21a among the plurality of electrode layers 21a in the stacked film 11a. The electrode layer 21bx is the lowermost electrode layer 21b among the plurality of electrode layers 21b in the stacked film 11b.

FIG. 6 further shows a plurality of contact plugs 37 in the insulating film 12a and a plurality of contact plugs 36 in the stacked film 11, similar to FIG. 5. Each contact plug 36 includes the plugs 36a and 36b, or includes only the plug 36b. In FIG. 6, each plug 36b is provided in the insulating film 11e and the stacked film 11b, or in the insulating film 11e, the stacked film 11b, and the insulating film 11d, or in the insulating film 11e, the stacked film 11b, the insulating film 11d, and the insulating film 11c, and each plug 36a is provided in the insulating film 11c and the stacked film 11a. In this manner, the semiconductor device according to this embodiment does not include the plug 36b provided only in the insulating film 11e or the plug 36a provided only in the insulating film 11c, but instead, includes the plug 36b provided in the insulating film 11e, the stacked film 11b, the insulating film 11d, and the insulating film 11c. In addition, the semiconductor device according to this embodiment includes the contact plug 37 provided in the insulating film 12a and the insulating film 11e. Further details of these contact plugs 36 and 37 will be described later.

FIG. 6 further shows a spacer insulating film 35 provided on the side surface of each contact plug 36. The side surface of each plug 36a is surrounded by the insulating film 35a in the spacer insulating film 35, and the side surface of each plug 36b is surrounded by the insulating film 35b in the spacer insulating film 35. Each of the plugs 36a and 36b has a solid columnar shape extending in the Z direction, and each of the insulating films 35a and 35b has a hollow columnar shape (that is, a tubular shape) extending in the Z direction. The insulating films 35a and 35b in this embodiment are, for example, SiO2 films. The side surface of each contact plug 37 in this embodiment is not surrounded by a spacer insulating film, but is instead surrounded by the insulating film 12a or the insulating film 11e.

Each plug 36a in this embodiment is provided on the lower surface of any one of the electrode layers 21a in the stacked film 11a, and penetrates one or more electrode layers 21a in the stacked film 11a via the insulating film 35a. As a result, each plug 36a in this embodiment is electrically connected to the former electrode layer 21a and electrically insulated from the latter electrode layer 21a. On the other hand, each plug 36b in this embodiment is provided on the lower surface of any one of the plugs 36a in the stacked film 11a, the electrode layer 21ax in the stacked film 11a, or any one of the electrode layers 21b in the stacked film 11b, and penetrates one or more electrode layers 21b in the stacked film 11b via the insulating film 35b. As a result, each plug 36b in this embodiment is electrically connected to the plug 36a, the electrode layer 21ax, or the former electrode layer 21b, and is electrically insulated from the latter electrode layer 21b.

The plugs 36a and 36b in this embodiment are formed by forming a plurality of holes in the stacked films 11a and 11b when performing the step shown in FIG. 3, and forming the plugs 36a and 36b in these holes via the insulating films 35a and 35b. Thus, each of the plugs 36a and 36b in this embodiment has a diameter that decreases in the +Z direction in FIG. 6, that is, has a tapered shape toward the +Z direction.

Similarly, the plurality of contact plugs 37 in this embodiment are formed by forming a plurality of contact holes in the insulating film 12 and forming the contact plugs 37 in these contact holes when performing the step shown in FIG. 3. Thus, in FIG. 6, each contact plug 37 in this embodiment has a diameter that decreases in the +Z direction, that is, has a tapered shape toward the +Z direction. The shape of the XY cross-section of each contact plug 37 in this embodiment is, for example, circular. This is the same for each plug 36a and each plug 36b in this embodiment.

FIG. 6 further shows six plugs C1 to C6 as an example of the plug C (see the description of FIG. 5) as in FIG. 5.

The plug C1 in this embodiment includes the plugs 36a and 36b and the contact plug 37 as in the comparative example, and is electrically connected to one electrode layer 21a other than the electrode layer 21ax as in the comparative example. This is the same for the plug C2 in this embodiment. On the other hand, the plug C3 in this embodiment is electrically connected to the electrode layer 21ax as in the comparative example, but includes only the plug 36b and the contact plug 37 unlike the comparative example. In the plug C3 in this embodiment, the plug 36b is provided in the stacked film 11b, the insulating film 11d, and the insulating film 11c.

The plug C4 in this embodiment includes the plug 36b and the contact plug 37 as in the comparative example, and is electrically connected to one electrode layer 21b other than the electrode layer 21bx as in the comparative example. This is the same for the plug C5 in this embodiment. On the other hand, the plug C6 in this embodiment is electrically connected to the electrode layer 21bx as in the comparative example, but includes only the contact plug 37 unlike the comparative example. In the plug C6 in this embodiment, the contact plug 37 is provided in the insulating film 12a and the insulating film 11e.

Symbols Pa, Pb, and Pc shown in FIG. 6 represent portions in each plug C, as in FIG. 5. The symbol Pa represents portions in the stacked film 11a and the insulating film 11c of each plug C. The symbol Pb represents portions in the stacked film 11b, the insulating film 11d, and the insulating film 11e of each plug C. The symbol Pc represents a portion in the insulating film 12a of each plug C. In each plug C, the portion Pa is located on the portion Pb, and the portion Pb is located on the portion Pc.

Each of the plugs C1 and C2 in this embodiment includes portions Pa, Pb, and Pc, and is electrically connected to any of the electrode layers 21a (except for the electrode layer 21ax) in the stacked film 11a. The portions Pa, Pb, and Pc of the plug C1 in this embodiment correspond to the plug 36a, the plug 36b, and the contact plug 37 of the plug C1, respectively. The portions Pa, Pb, and Pc of the plug C2 in this embodiment correspond to the plug 36a, the plug 36b, and the contact plug 37 of the plug C2, respectively. The above is the same as in the comparative example.

The plug C3 in this embodiment includes portions Pa, Pb, and Pc, and is electrically connected to the electrode layer 21ax in the stacked film 11a. The above is the same as in the comparative example. On the other hand, the portions Pa and Pb of the plug C3 in this embodiment correspond to the plug 36b of the plug C3, and the portion Pc of the plug C3 in this embodiment corresponds to the contact plug 37 of the plug C3. The portion Pa of the plug C3 is formed with the plug 36a in the comparative example, but is formed with the plug 36b in this embodiment. The portions Pa, Pb, and Pc of the plug C3 are examples of a fourth portion, a third portion, and a tenth portion, respectively.

Each of the plugs C4 and C5 in this embodiment includes only the portions Pb and Pc, and is electrically connected to any of the electrode layers 21b (except for the electrode layer 21bx) in the stacked film 11b. The portions Pb and Pc of the plug C4 in this embodiment correspond to the plug 36b and the contact plug 37 of the plug C4, respectively. The portions Pb and Pc of the plug C5 in this embodiment correspond to the plug 36b and the contact plug 37 of the plug C5, respectively. The above is the same as in the comparative example.

The plug C6 in this embodiment includes only the portions Pb and Pc, and is electrically connected to the electrode layer 21bx in the stacked film 11b. The above is the same as in the comparative example. Meanwhile, the portions Pb and Pc of the plug C6 in this embodiment correspond to the contact plug 37 of the plug C6. The portion Pb of the plug C6 is formed with the plug 36b in the comparative example, but is formed with the contact plug 37 in this embodiment. In this embodiment, the portion Pb of the plug C6 is formed with the contact plug 37, not the plug 36b, and thus the side surface of the portion Pb of the plug C6 is not surrounded by the insulating film 35b.

In this embodiment, the boundary between the portion Pa and the portion Pb of the plug C1 is located at the boundary between the plug 36a and the plug 36b. As a result, the diameter of the plug C1 changes discontinuously at the boundary between the portion Pa and the portion Pb in the Z direction. In FIG. 6, the diameter of the lower end of the portion Pa of the plug C1 is larger than the diameter of the upper end of the portion Pb of the plug C1. In this embodiment, such discontinuity is also seen in a taper angle of the side surface of the plug C1. In the plug C1 shown in FIG. 6, a taper angle of the side surface of the portion Pa at the lower end of the portion Pa is different from a taper angle of the side surface of the portion Pb at the upper end of the portion Pb. The above is the same for the plug C2.

On the other hand, in this embodiment, the boundary between the portion Pa and the portion Pb of the plug C3 is located between the upper end and the lower end of the plug 36b. As a result, the diameter of the plug C3 changes continuously at the boundary between the portion Pa and the portion Pb in the Z direction. In FIG. 6, the diameter of the plug C3 near the boundary between the portion Pa and the portion Pb gradually decreases in the +Z direction. In this embodiment, such continuity is also seen in a taper angle of the side surface of the plug C3. In the plug C3 shown in FIG. 6, a taper angle of the side surface of the portion Pa at the lower end of the portion Pa is the same as a taper angle of the side surface of the portion Pb at the upper end of the portion Pb.

Further, in this embodiment, the boundary between the portion Pb and the portion Pc of the plug C4 is located at the boundary between the plug 36b and the contact plug 37. As a result, the diameter of the plug C4 changes discontinuously at the boundary between the portion Pb and the portion Pc in the Z direction. In FIG. 6, the diameter of the lower end of the portion Pb of the plug C4 is larger than the diameter of the upper end of the portion Pc of the plug C4. In this embodiment, such discontinuity is also seen in a taper angle of the side surface of the plug C4. In the plug C4 shown in FIG. 6, a taper angle of the side surface of the portion Pb at the lower end of the portion Pb is different from a taper angle of the side surface of the portion Pc at the upper end of the portion Pc. The above is the same for the plug C5 and the plugs C1 to C3.

On the other hand, in this embodiment, the boundary between the portion Pb and the portion Pc of the plug C6 is located between the upper end and the lower end of the contact plug 37. As a result, the diameter of the plug C6 changes continuously at the boundary between the portion Pb and the portion Pc in the Z direction. In FIG. 6, the diameter of the plug C6 near the boundary between the portion Pb and the portion Pc gradually decreases in the +Z direction. Such continuity is also seen in a taper angle of the side surface of the plug C6 in this embodiment. In the plug C6 shown in FIG. 6, the taper angle of the side surface of the portion Pb at the lower end of the portion Pb is the same as the taper angle of the side surface of the portion Pc at the upper end of the portion Pc.

As described above, in the comparative example, when the semiconductor device is manufactured, it is difficult to preferably form the plugs C1 to C6 due to the insulating films 11c, 11d, 11e, 12a, 22a, 22b, and the like. Specifically, it is difficult to preferably form the contact hole for the contact plug 36. On the other hand, according to this embodiment, it is possible to set the shapes of the plugs C3 and C6 as described above. Further details of such effects will be described later.

The semiconductor device according to this embodiment further includes a plurality of plugs C (not shown) other than the plugs C1 to C6. Each of the electrode layers 21a and 21b in this embodiment is electrically connected to any one of the plugs C. The plugs C electrically connected to the electrode layers 21a other than the electrode layer 21ax can be formed in the same manner as the plugs C1 and C2. Furthermore, the plugs C electrically connected to the electrode layers 21b other than the electrode layer 21bx can be formed in the same manner as the plugs C4 and C5. Although the plugs C1 to C6 in this embodiment are arranged in the X direction in FIG. 6, the plugs C1 to C6 may be arranged in other layouts in the region R2. This is the same for the plurality of plugs C (not shown) mentioned above other than the plugs C1 to C6.

The stacked film 11 in this embodiment may further include one or more stacked films between the stacked film 11a and the stacked film 11b. In this case, each stacked film between the stacked film 11a and the stacked film 11b may have a structure similar to those of the stacked films 11a and 11b. The plugs C for each stacked film between the stacked film 11a and the stacked film 11b may have a shape similar to those of the plugs C1 to C3 in this embodiment.

Regarding the plugs C1 to C3 in this embodiment, the plugs 36a and 36b and the contact plugs 37 in each plug C may be formed with the same material layer or different material layers. Similarly, regarding the plugs C4 to C6 in this embodiment, the plug 36b and the contact plug 37 in each plug C may be formed with the same material layer or different material layers. In the following description, an example will be described in which the plugs 36a and 36b and the contact plug 37 in the plugs C1 to C6 are formed with the same material layer. The material layer is, for example, a metal layer including a W layer.

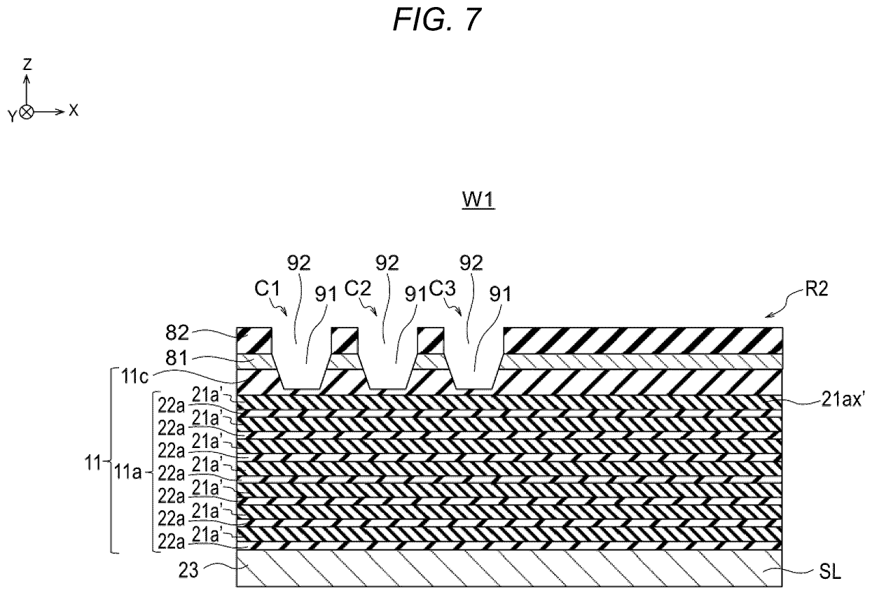

Next, a method of manufacturing the semiconductor device according to this embodiment will be described in comparison with the comparative example with reference to FIGS. 7 to 40.

FIGS. 7 to 22 are cross-sectional views showing a method of manufacturing the semiconductor device according to the comparative example.

FIGS. 7 to 22 show steps of forming the structure shown in FIG. 5. The steps shown in FIGS. 7 to 22 correspond to some of the steps shown in FIG. 3.

First, the wiring layer 23, the stacked film 11a, the insulating film 11c, a hard mask layer 81, and a resist layer 82 are formed in this order above the substrate 15 (not shown) of the array wafer W1 (FIG. 7). The hard mask layer 81 is, for example, a polysilicon layer. The stacked film 11a shown in FIG. 7 is formed to include a plurality of sacrifice layers 21a′ and a plurality of insulating films 22a alternately. These sacrifice layers 21a′ in the stacked film 11a are spaced apart from each other in the Z direction. Each sacrifice layer 21a′ is, for example, a SiN film. The sacrifice layer 21ax′ shown in FIG. 7 is the uppermost sacrifice layer 21a′ among the plurality of sacrifice layers 21a′ of the stacked film 11a.

Next, the resist layer 82, the hard mask layer 81, and the insulating film 11c are etched by lithography and reactive ion etching (RIE) (FIG. 7). As a result, a plurality of recess portions 92 are formed in the resist layer 82, these recess portions 92 are transferred to the hard mask layer 81 and the insulating film 11c, and a plurality of recess portions 91 are formed in the hard mask layer 81 and the insulating film 11c. These recess portions 91 are formed to be used as holes in which the plugs 36a of the plugs C1 to C3 are embedded. Each recess portion 91 shown in FIG. 7 is formed such that the insulating film 11c having a film thickness substantially the same as the film thickness of the insulating film 22a remains under each recess portion 91. The planar shape of each recess portion 92 of the resist layer 82 is, for example, circular.

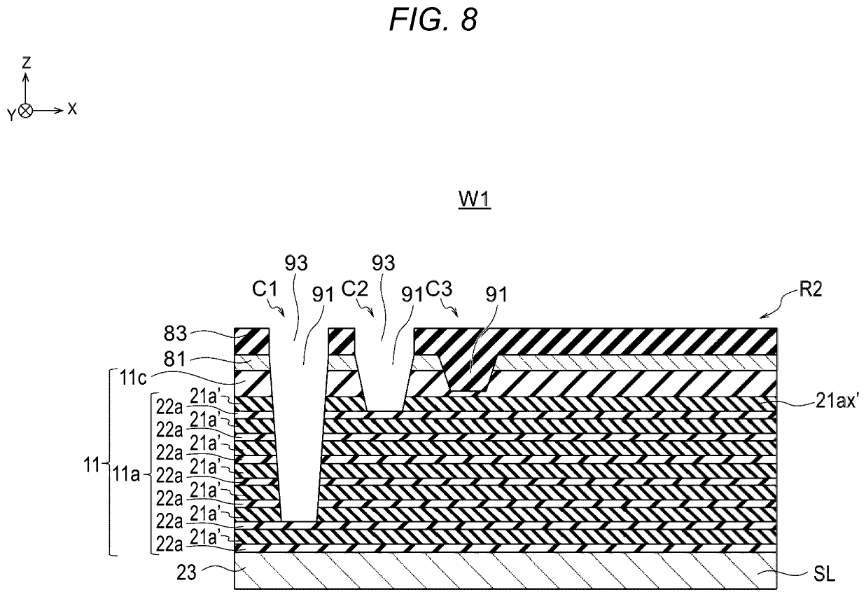

Next, after the resist layer 82 is removed, a resist layer 83 is formed on the hard mask layer 81 (FIG. 8). As a result, the recess portions 91 for the plugs C1 to C3 are filled with the resist layer 83.

Next, the resist layer 83, the insulating film 11c, and the stacked film 11a are etched by lithography and RIE (FIG. 8). As a result, a plurality of recess portions 93 are formed in the resist layer 83, the resist layer 83 is removed from the recess portions 91 for the plugs C1 and C2, and the stacked film 11a in these recess portions 91 is further etched. Meanwhile, the resist layer 83 is left in the recess portions 91 for the plug C3. The etching of the stacked film 11a in FIG. 8 is performed such that the bottom surfaces of each of the recess portions 91 for the plugs C1 and C2 reach the upper surface of a predetermined insulating film 22a. The planar shape of each recess portion 93 in the resist layer 83 is, for example, circular.

In the step shown in FIG. 8, etching for processing the recess portions 91 for the plug C1 and etching for processing the recess portions 91 for the plug C2 may be performed simultaneously or sequentially. In the latter case, etching for processing the recess portions 91 for the plug C1 and etching for processing the recess portions 91 for the plug C2 are performed using, for example, separate resist layers 83.

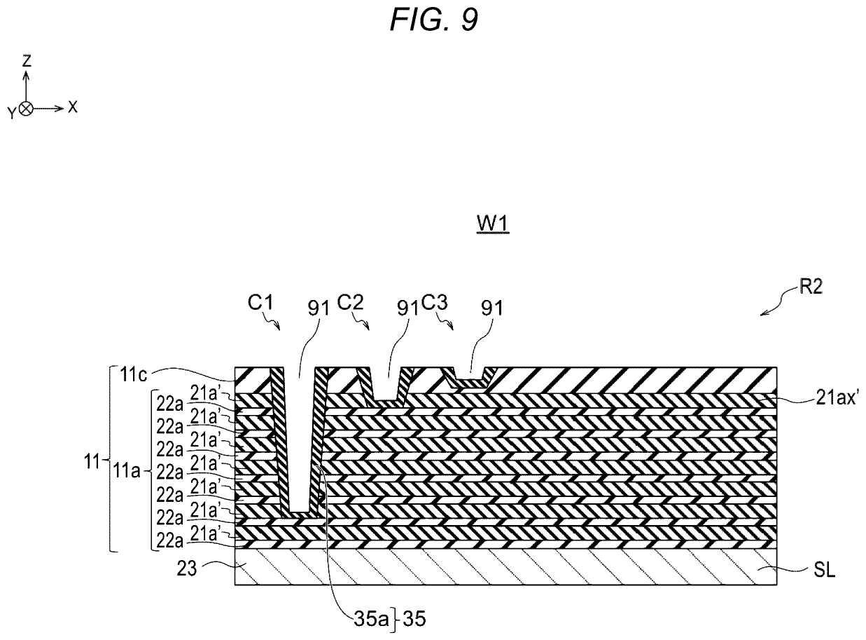

Next, after the resist layer 83 and the hard mask layer 81 are removed, the insulating film 35a of the spacer insulating film 35 is formed in each recess portion 91 (FIG. 9). As a result, the insulating film 35a is formed on the side surface and bottom surface of each recess portion 91.

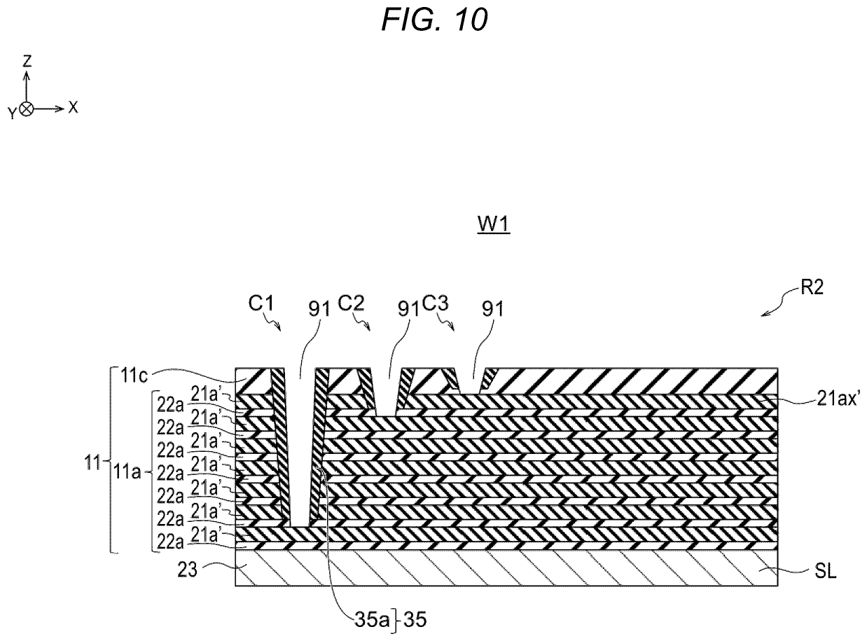

Next, the insulating film 35a is removed from the bottom surface of each recess portion 91 by lithography and RIE (FIG. 10). At this time, one insulating film 22a is further removed from the bottom surface of the recess portion 91 for the plug C1, one insulating film 22a is further removed from the bottom surface of the recess portion 91 for the plug C2, and one insulating film 11c is further removed from the bottom surface of the recess portion 91 for the plug C3. As a result, the bottom surfaces of the recess portions 91 for the plugs C1 to C3 reach the upper surface of the predetermined sacrifice layer 21a′. The reason why the insulating film 11c having a film thickness substantially the same as the film thickness of the insulating film 22a is left under each recess portion 91 in the step shown in FIG. 7 is to facilitate simultaneous etching of the insulating film 22a under the recess portions 91 for the plugs C1 and C2 and the insulating film 11c under the recess portion 91 for the plug C3 in the step shown in FIG. 10.

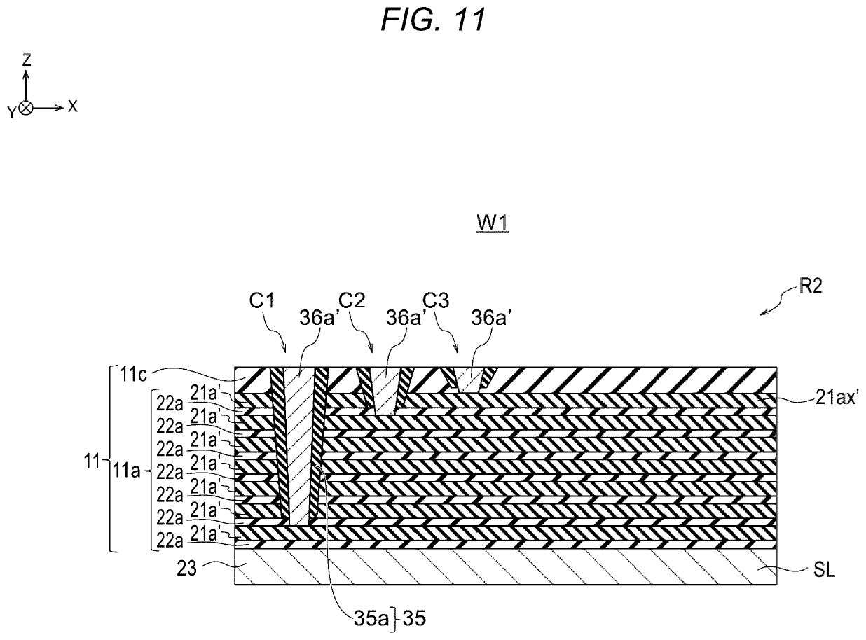

Next, a sacrifice layer 36a′ is embedded in each recess portion 91 (FIG. 11). As a result, the sacrifice layer 36a′ is formed on the predetermined sacrifice layer 21a′ in each recess portion 91. The sacrifice layer 36a′ is, for example, a polysilicon layer.

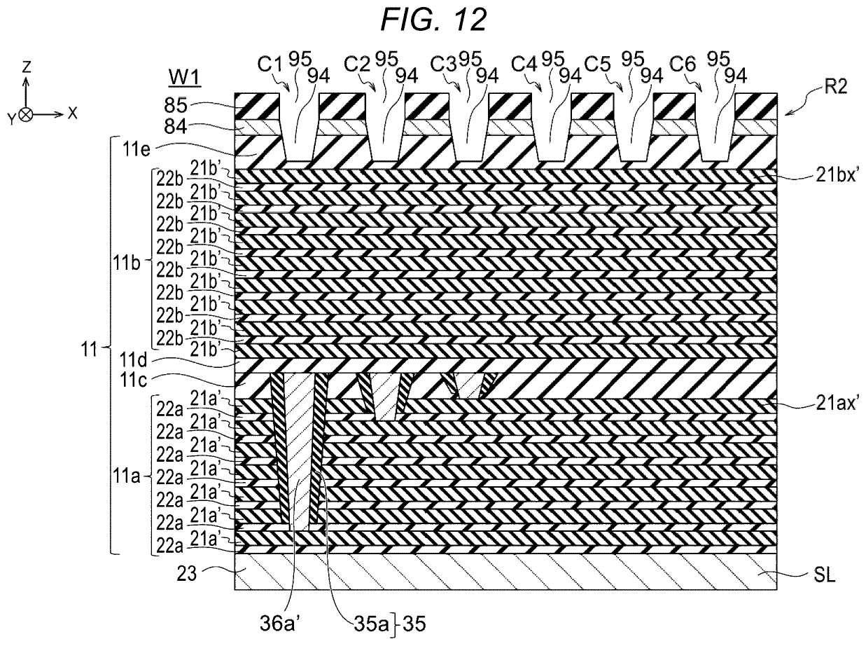

Next, the insulating film 11d, the stacked film 11b, the insulating film 11e, the hard mask layer 84, and the resist layer 85 are formed in this order on the insulating film 11c, the insulating film 35a, and the sacrifice layer 36a′ (FIG. 12). The hard mask layer 84 is, for example, a polysilicon layer. The stacked film 11b shown in FIG. 12 is formed to include a plurality of sacrifice layers 21b′ and a plurality of insulating films 22b alternately. These sacrifice layers 21b′ in the stacked film 11b are spaced apart from each other in the Z direction. Each sacrifice layer 21b′ is, for example, a SiN film. A sacrifice layer 21bx′ shown in FIG. 12 is the uppermost sacrifice layer 21b′ among the plurality of sacrifice layers 21b′ of the stacked film 11b.

Next, the resist layer 85, the hard mask layer 84, and the insulating film 11e are etched by lithography and RIE (FIG. 12). As a result, a plurality of recess portions 95 are formed in the resist layer 85, these recess portions 95 are transferred to the hard mask layer 84 and the insulating film 11e, and a plurality of recess portions 94 are formed in the hard mask layer 84 and the insulating film 11e. These recess portions 94 are formed to be used as holes in which the plugs 36b of the plugs C1 to C6 are embedded. Each recess portion 94 shown in FIG. 12 is formed such that the insulating film 11e having a film thickness substantially the same as the film thickness of the insulating film 22b remains under each recess portion 94. The planar shape of each recess portion 95 in the resist layer 85 is, for example, circular.

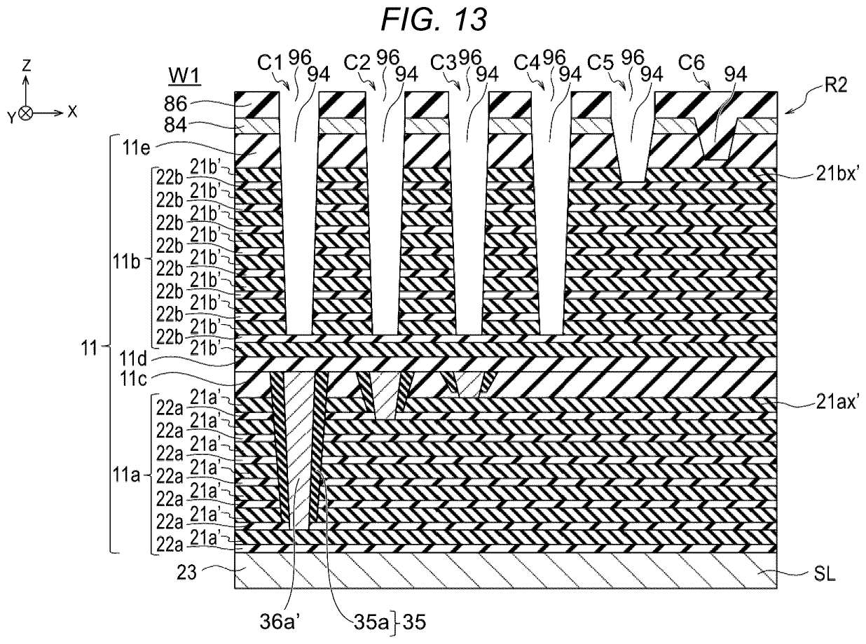

Next, after the resist layer 85 is removed, a resist layer 86 is formed on the hard mask layer 84 (FIG. 13). As a result, the recess portions 94 for the plugs C1 to C6 are filled with the resist layer 86.

Next, the resist layer 86, the insulating film 11e, and the stacked film 11b are etched by lithography and RIE (FIG. 13). As a result, a plurality of recess portions 96 are formed in the resist layer 86, the resist layer 86 is removed from the recess portions 94 for the plugs C1 to C5, and the stacked film 11b in these recess portions 94 is further etched. Meanwhile, the resist layer 86 is left in the recess portion 94 for the plug C6. The etching of the stacked film 11b in FIG. 13 is performed such that the bottom surfaces of the recess portions 94 for the plugs C1 to C5 reach the upper surface of a predetermined insulating film 22b. The planar shape of each of the recess portions 96 in the resist layer 86 is, for example, circular.

In the step shown in FIG. 13, etching for processing the recess portions 94 for the plugs C1 to C5 may be performed simultaneously or sequentially. For example, etching for processing the recess portions 94 for the plugs C1 to C4 may be performed simultaneously, and etching for processing the recess portions 94 for the plugs C1 to C4 and etching for processing the recess portions 94 for the plug C5 may be performed sequentially. In this case, etching for processing the recess portions 94 for the plugs C1 to C4 and etching for processing the recess portions 94 for the plug C5 are performed using, for example, separate resist layers 86.

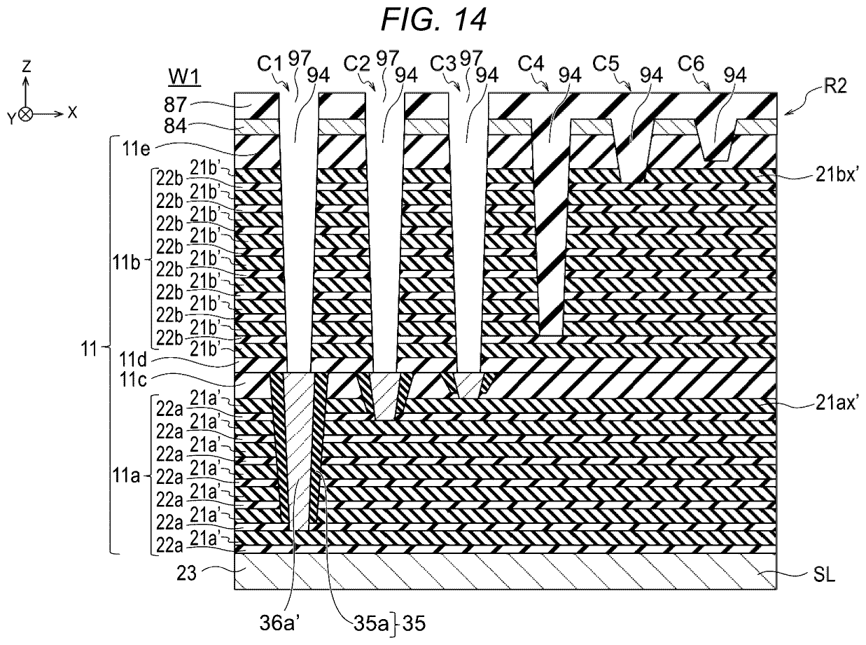

Next, after the resist layer 86 is removed, a resist layer 87 is formed on the hard mask layer 84 (FIG. 14). As a result, the recess portions 94 for the plugs C1 to C6 are filled with the resist layer 87.

Next, the resist layer 87, the stacked film 11b, and the insulating film 11d are etched by lithography and RIE (FIG. 14). As a result, a plurality of recess portions 97 are formed in the resist layer 87, the resist layer 87 is removed from the recess portions 94 for the plugs C1 to C3, and the stacked film 11b and the insulating film 11d in these recess portions 94 are further etched. Meanwhile, the resist layer 87 is left in the recess portions 94 for the plugs C4 to C6. The etching of the stacked film 11b and the insulating film 11d in FIG. 14 is performed such that the bottom surfaces of the recess portions 94 for the plugs C1 to C3 reach the upper surface of the corresponding sacrifice layer 36a′. The planar shape of each recess portion 97 in the resist layer 87 is, for example, circular.

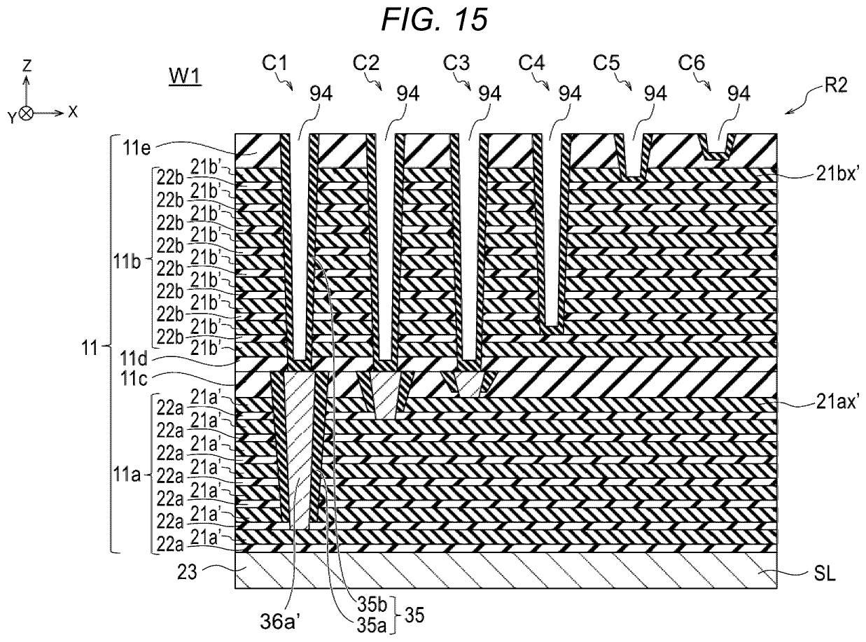

Next, after the resist layer 87 and the hard mask layer 84 are removed, the insulating film 35b of the spacer insulating film 35 is formed in each recess portion 94 (FIG. 15). As a result, the insulating film 35b is formed on the side surface and bottom surface of each recess portion 94.

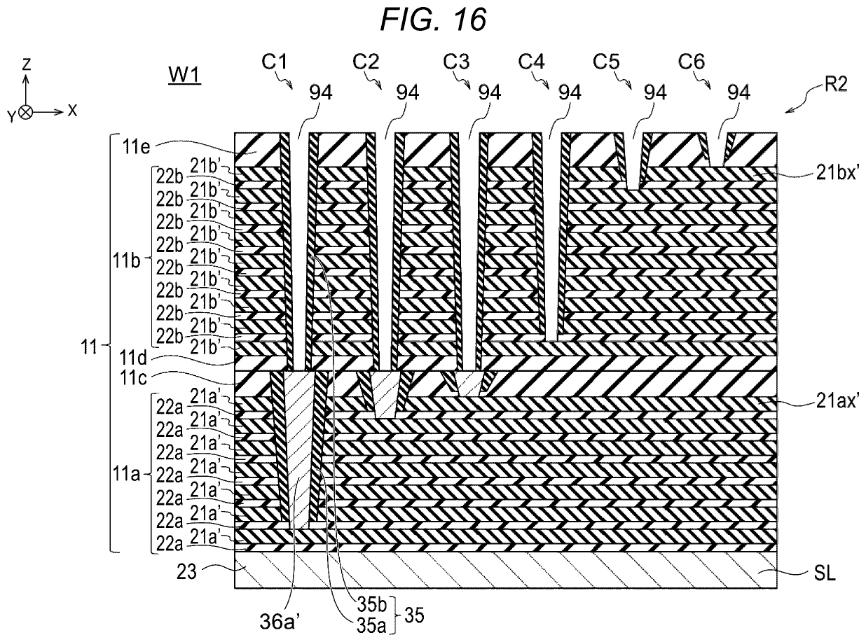

Next, the insulating film 35b is removed from the bottom surface of each recess portion 94 by lithography and RIE (FIG. 16). At this time, one insulating film 22b is further removed from the bottom surface of the recess portion 94 for the plug C4, one insulating film 22b is further removed from the bottom surface of the recess portion 94 for the plug C5, and the insulating film 11e is further removed from the bottom surface of the recess portion 94 for the plug C6. As a result, the bottom surfaces of the recess portions 94 for the plugs C4 to C6 reach the upper surface of a predetermined sacrifice layer 21b′. The reason why the insulating film 11e having a film thickness substantially the same as the film thickness of the insulating film 22b is left under each recess portion 94 in the step shown in FIG. 12 is to facilitate simultaneous etching of the insulating film 22b under the recess portions 94 for the plugs C4 and C5 and the insulating film 11e under the recess portion 94 for the plug C6 in the step shown in FIG. 16.

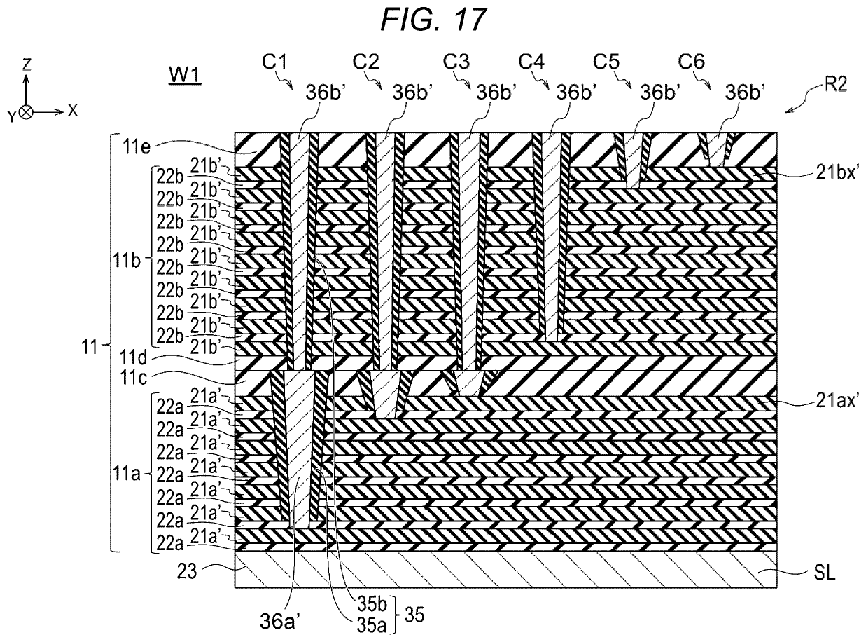

Next, a sacrifice layer 36b′ is embedded in each recess portion 94 (FIG. 17). As a result, the sacrifice layer 36b′ is formed on a predetermined sacrifice layer 21a′ or sacrifice layer 36a′ in each recess portion 94. The sacrifice layer 36b′ is, for example, a polysilicon layer.

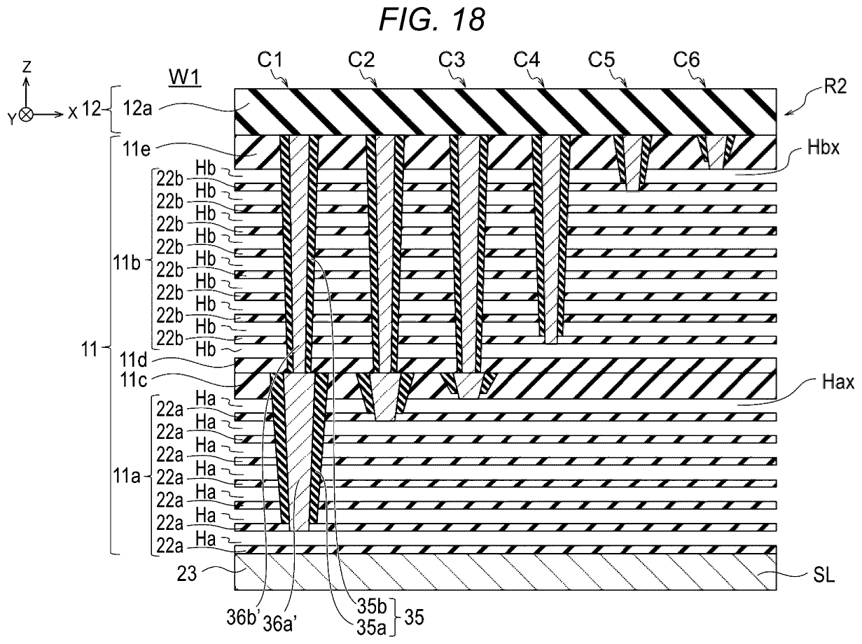

Next, an insulating film 12a for the interlayer insulating film 12 is formed on the insulating film 11e, the insulating film 35b, and the sacrifice layer 36b′ (FIG. 18). Next, a plurality of slits (not shown) penetrating the insulating film 12a, the insulating film 11e, the stacked film 11b, the insulating film 11d, the insulating film 11c, and the stacked film 11a are formed, and the sacrifice layers 21a′ and 21b′ are removed from the stacked films 11a and 11b by wet etching through these slits (FIG. 18). As a result, a plurality of recess portions Ha are formed in the stacked film 11a, and a plurality of recess portions Hb are formed in the stacked film 11b. The recess portion Hax shown in FIG. 18 is the uppermost recess portion Ha among the plurality of recess portions Ha in the stacked film 11a. The recess portion Hbx shown in FIG. 18 is the uppermost recess portion Hb among the plurality of recess portions Hb in the stacked film 11b.

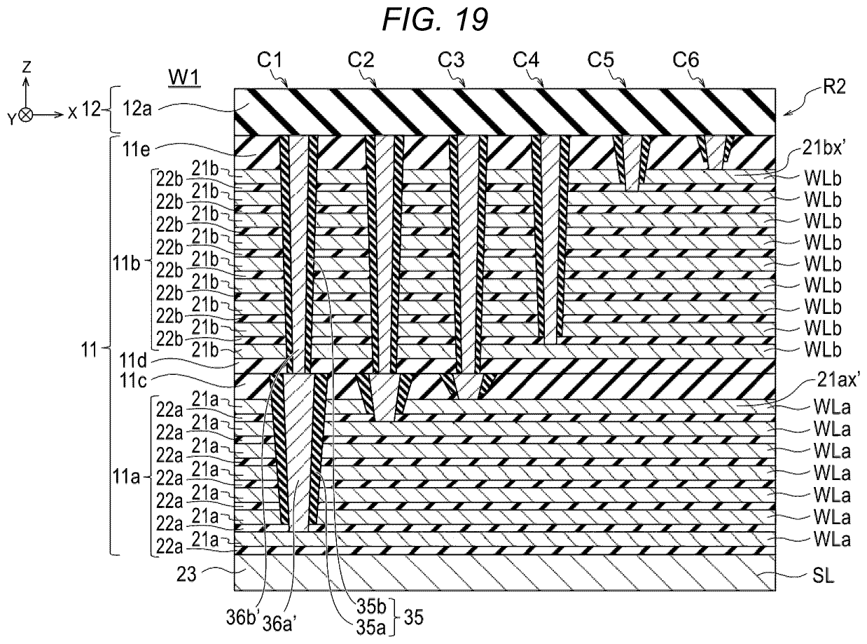

Next, the electrode layers 21a and 21b corresponding to the word lines WLa, WLb are respectively formed in the recess portions Ha and Hb from the above-mentioned slits (FIG. 19). In this manner, the sacrifice layers 21a′ and 21b′ are replaced with the electrode layers 21a and 21b, respectively, to form the stacked film 11 including the electrode layers 21a and 21b. The electrode layer 21ax shown in FIG. 19 is the uppermost electrode layer 21a among the plurality of electrode layers 21a of the stacked film 11a. The electrode layer 21bx shown in FIG. 19 is the uppermost electrode layer 21b among the plurality of electrode layers 21b of the stacked film 11b. The electrode layers 21a and 21b are formed, for example, by sequentially filling the recess portions Ha and Hb with a barrier metal layer (for example, a TiN film (titanium nitride film)) and an electrode material layer (for example, a W layer).

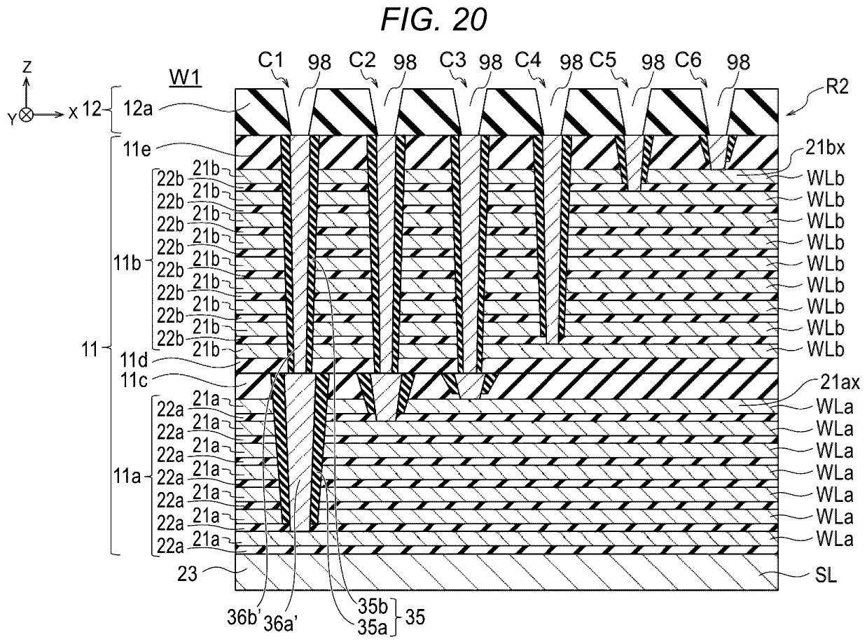

Next, the insulating film 12a is etched by RIE (FIG. 20). As a result, a plurality of recess portions 98 are formed in the insulating film 12a. These recess portions 98 are formed to be used as contact holes in which the contact plugs 37 of the plugs C1 to C6 are embedded. The etching of the insulating film 12a in FIG. 20 is performed such that the bottom surfaces of the recess portions 98 for the plugs C1 to C6 reach the upper surface of the corresponding sacrifice layer 36b′.

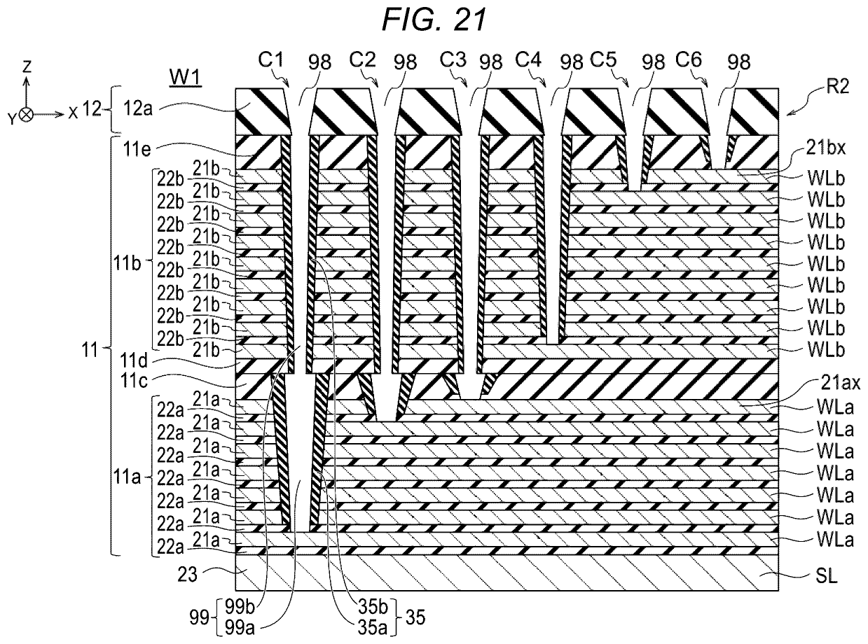

Next, the sacrifice layers 36a′ and 36b′ for the plugs C1 to C6 are removed from the stacked film 11 by etching from the recess portions 98 (FIG. 21). As a result, recess portions 99 for the plugs C1 to C6 are formed in the stacked film 11. These recess portions 99 are formed to be used as contact holes in which the contact plugs 36 of the plugs C1 to C6 are embedded. Each of the recess portions 99 for the plugs C1 to C3 includes a recess portion 99a corresponding to the recess portion 91 and a recess portion 99b corresponding to the recess portion 94. On the other hand, each of the recess portions 99 for the plugs C4 to C6 includes only a recess portion 99b corresponding to the recess portion 94.

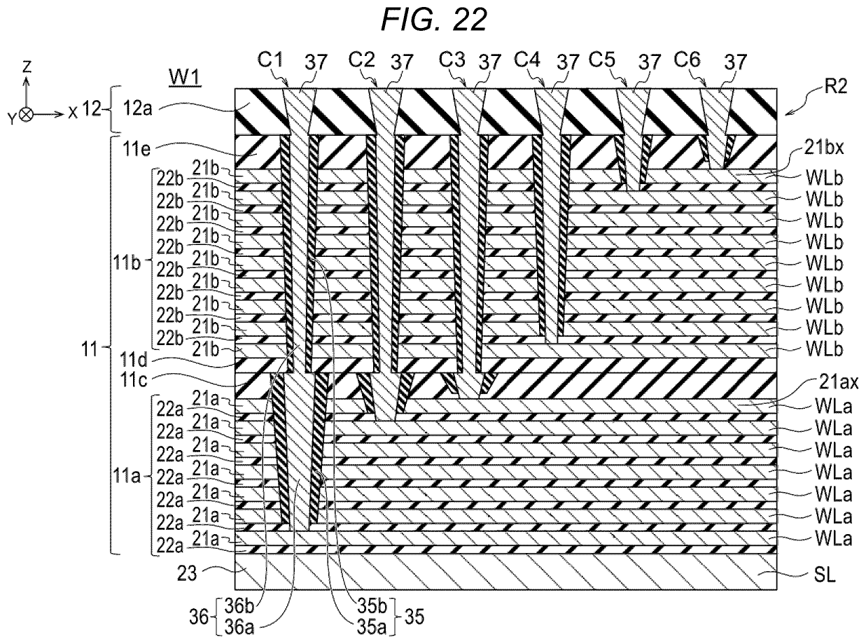

Next, material layers for the contact plugs 36 and 37 are embedded in the recess portions 98 and 99 for the plugs C1 to C6 (FIG. 22). As a result, the contact plugs 37 and 36 are formed in the recess portions 98 and 99, respectively. Specifically, the plugs 36a and 36b are formed in the recess portions 99a and 99b, respectively. Each of the plugs C1 to C3 is formed on the corresponding electrode layer 21a, and each of the plugs C4 to C6 is formed on the corresponding electrode layer 21b. The above-mentioned material layers are formed to include, for example, a barrier metal layer (for example, a TiN film) and a plug material layer (for example, a W layer) in that order. In this manner, the structure shown in FIG. 7 is formed.

In this comparative example, when the semiconductor device is manufactured, it is difficult to preferably form the plugs C1 to C6 due to the insulating films 11c, 11d, 11e, 12a, 22a, 22b, and the like. For example, it is difficult to leave the insulating film 11c having a film thickness substantially the same as the film thickness of the insulating film 22a under each recess portion 91 in the step shown in FIG. 7 and it is difficult to leave the insulating film 11e having a film thickness substantially the same as the film thickness of the insulating film 22b under each recess portion 94 in the step shown in FIG. 12. Thereby, it is difficult to preferably form the recess portions 91 and 94 for the plugs C1 to C6. Further details of this problem will be described later.

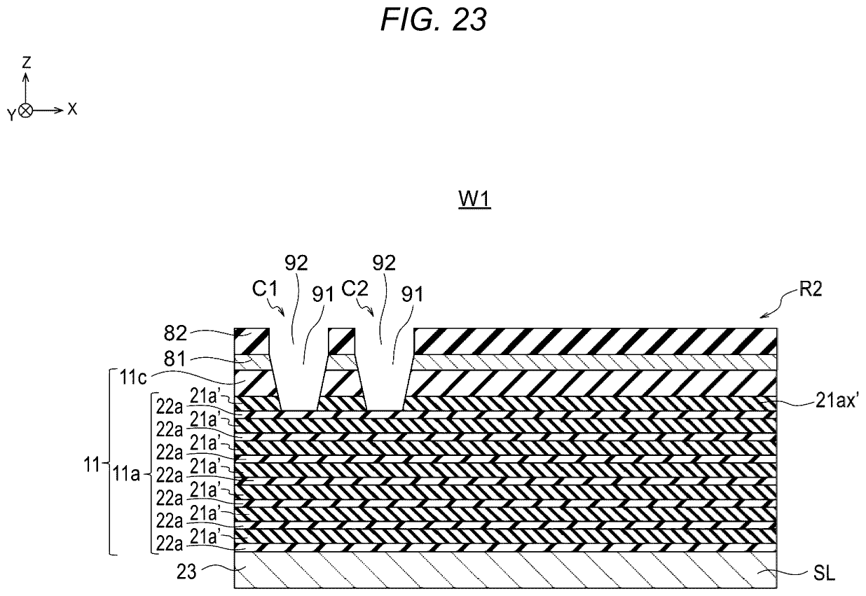

FIGS. 23 to 40 are cross-sectional views showing a method of manufacturing the semiconductor device according to the first embodiment.

FIGS. 23 to 40 show steps of forming the structure shown in FIG. 6. The steps shown in FIGS. 23 to 40 correspond to some of the steps shown in FIG. 3. In the following description of FIGS. 23 to 40, the description of the points in common with FIGS. 7 to 22 will be omitted to some extent, and the description will be given focusing on the differences from FIGS. 7 to 22.

First, the wiring layer 23, the stacked film 11a, the insulating film 11c, the hard mask layer 81, and the resist layer 82 are formed in this order above the substrate 15 (not shown) of the array wafer W1 (FIG. 23). The stacked film 11a shown in FIG. 23 is formed to include a plurality of sacrifice layers 21a′ and a plurality of insulating films 22a alternately. The sacrifice layer 21ax′ shown in FIG. 23 is the uppermost sacrifice layer 21a′ among the plurality of sacrifice layers 21a′ of the stacked film 11a.

Next, the resist layer 82, the hard mask layer 81, the insulating film 11c, and the sacrifice layer 21ax′ are etched by lithography and RIE (FIG. 23). As a result, a plurality of recess portions 92 are formed in the resist layer 82, these recess portions 92 are transferred to the hard mask layer 81, the insulating film 11c, and the sacrifice layer 21ax′, and a plurality of recess portions 91 are formed in the hard mask layer 81, the insulating film 11c, and the sacrifice layer 21ax′. These recess portions 91 are formed to be used as holes in which the plugs 36a of the plugs C1 and C2 are embedded. Each recess portion 91 shown in FIG. 7 (i.e., the comparative example) is formed such that the insulating film 11c having a film thickness substantially the same as the film thickness of the insulating film 22a remains under each recess portion 91, while each recess portion 91 shown in FIG. 23 (i.e., this embodiment) is formed to penetrate the sacrifice layer 21ax′.

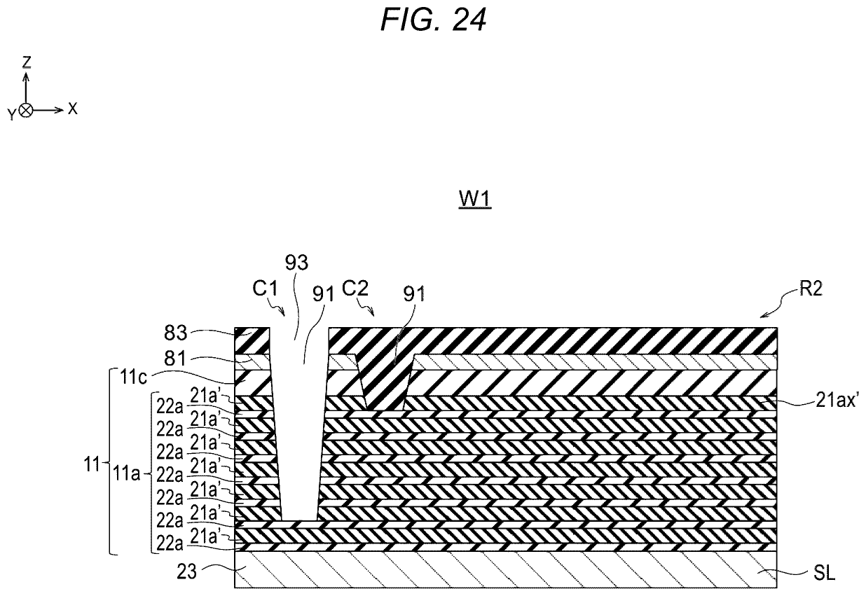

Next, after the resist layer 82 is removed, the resist layer 83 is formed on the hard mask layer 81 (FIG. 24). As a result, the recess portions 91 for the plugs C1 and C2 are filled with the resist layer 83.

Next, the resist layer 83 and the stacked film 11a are etched by lithography and RIE (FIG. 24). As a result, a recess portion 93 is formed in the resist layer 83, the resist layer 83 is removed from the recess portion 91 for the plug C1, and the stacked film 11a in the recess portion 91 is further etched. Meanwhile, the resist layer 83 is left in the recess portion 91 for the plug C2. The etching of the stacked film 11a in FIG. 24 is performed such that the bottom surface of the recess portion 91 for the plug C1 reaches the upper surface of the predetermined insulating film 22a. Since the bottom surface of the recess portion 91 for the plug C2 reaches the upper surface of the predetermined insulating film 22a in the step shown in FIG. 23, the recess portion 91 for the plug C2 is not etched in the step shown in FIG. 24.

When the recess portions 91 for the plugs C1 and C2 are etched in the step shown in FIG. 24, etching for processing the recess portion 91 for the plug C1 and etching for processing the recess portion 91 for the plug C2 may be performed simultaneously or sequentially in the step shown in FIG. 24. In the latter case, etching for processing the recess portion 91 for the plug C1 and etching for processing the recess portion 91 for the plug C2 are performed using, for example, separate resist layers 83.

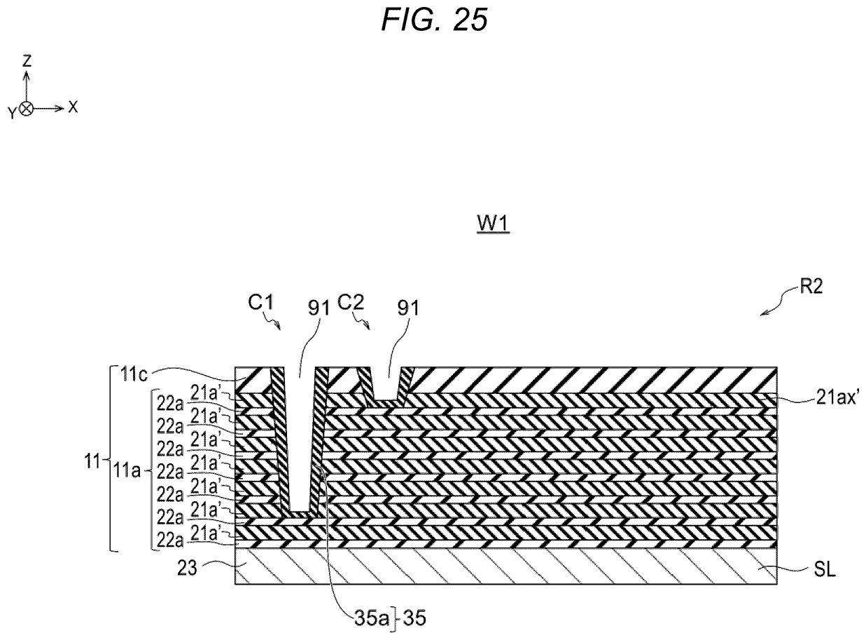

Next, after the resist layer 83 and the hard mask layer 81 are removed, the insulating film 35a of the spacer insulating film 35 is formed in each recess portion 91 (FIG. 25). As a result, the insulating film 35a is formed on the side surface and bottom surface of each recess portion 91.

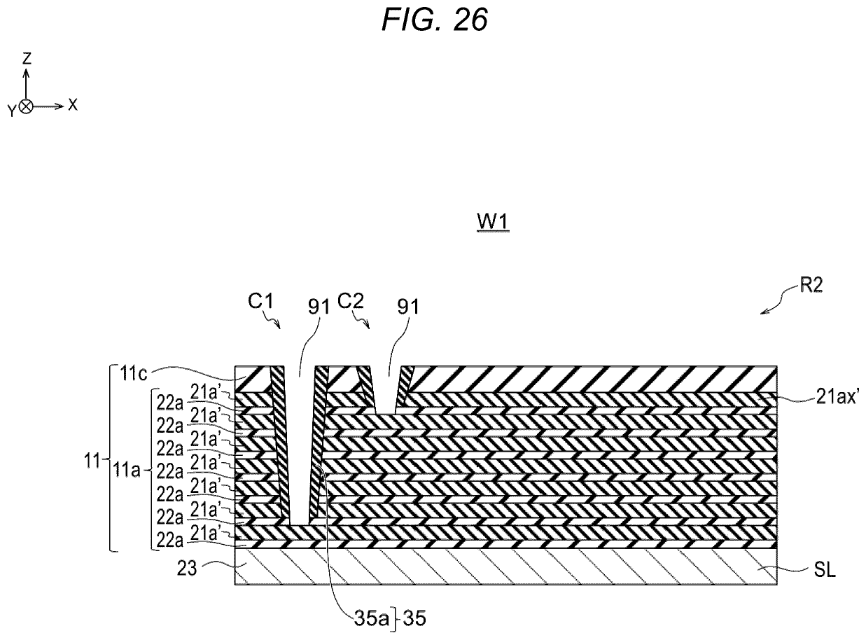

Next, the insulating film 35a is removed from the bottom surface of each recess portion 91 by lithography and RIE (FIG. 26). At this time, one insulating film 22a is further removed from the bottom surface of the recess portion 91 for the plug C1, and one insulating film 22a is further removed from the bottom surface of the recess portion 91 for the plug C2. As a result, the bottom surfaces of the recess portions 91 for the plugs C1 and C2 reach the upper surface of the predetermined sacrifice layer 21a′.

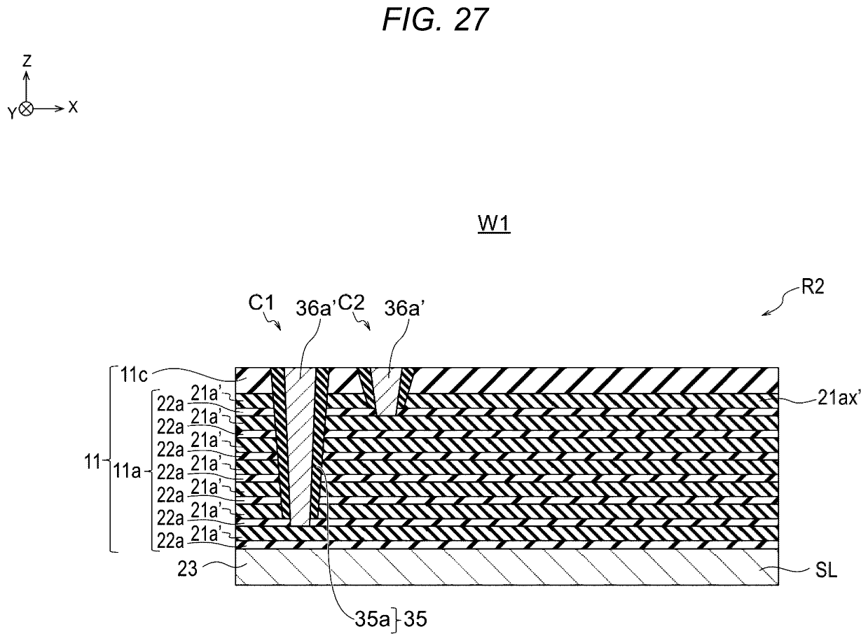

Next, the sacrifice layer 36a′ is embedded in each recess portion 91 (FIG. 27). As a result, the sacrifice layer 36a′ is formed on the predetermined sacrifice layer 21a′ in each recess portion 91. The sacrifice layer 36a′ is an example of a first film.

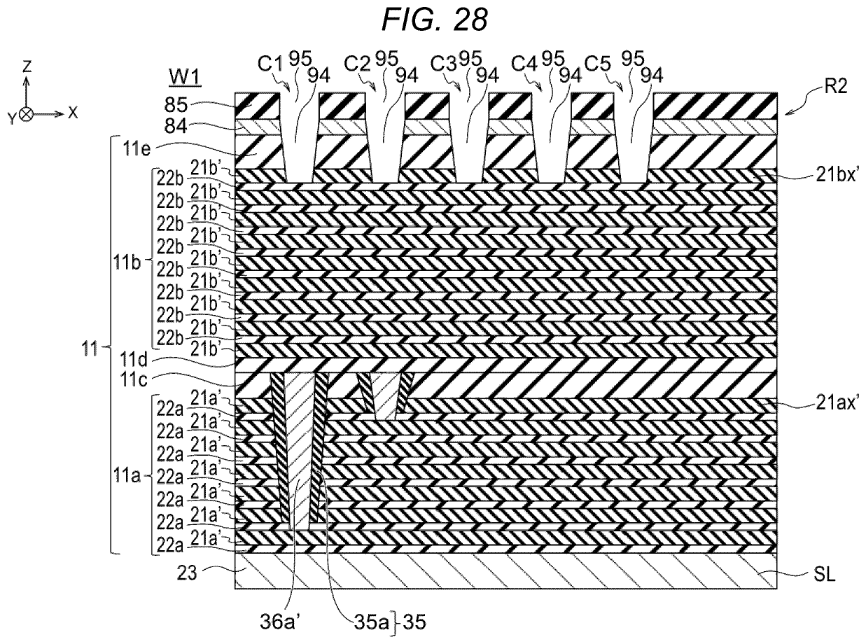

Next, the insulating film 11d, the stacked film 11b, the insulating film 11e, the hard mask layer 84, and the resist layer 85 are formed in this order on the insulating film 11c, the insulating film 35a, and the sacrifice layer 36a′ (FIG. 28). The stacked film 11b shown in FIG. 28 is formed to include a plurality of sacrifice layers 21b′ and a plurality of insulating films 22b alternately. The sacrifice layer 21bx′ shown in FIG. 28 is the uppermost sacrifice layer 21b′ among the plurality of sacrifice layers 21b′ of the stacked film 11b.

Next, the resist layer 85, the hard mask layer 84, the insulating film 11e, and the sacrifice layer 21bx′ are etched by lithography and RIE (FIG. 28). As a result, a plurality of recess portions 95 are formed in the resist layer 85, these recess portions 95 are transferred to the hard mask layer 84, the insulating film 11e, and the sacrifice layer 21bx′, and a plurality of recess portions 94 are formed in the hard mask layer 84, the insulating film 11e, and the sacrifice layer 21bx′. These recess portions 94 are formed to be used as holes in which the plugs 36b of the plugs C1 to C5 are embedded. Each recess portion 94 shown in FIG. 12 (i.e., the comparative example) is formed such that the insulating film 11e having a film thickness substantially the same as the film thickness of the insulating film 22b remains under each recess portion 94, while each recess portion 94 shown in FIG. 28 (i.e., the this embodiment) is formed to penetrate the sacrifice layer 21bx′.

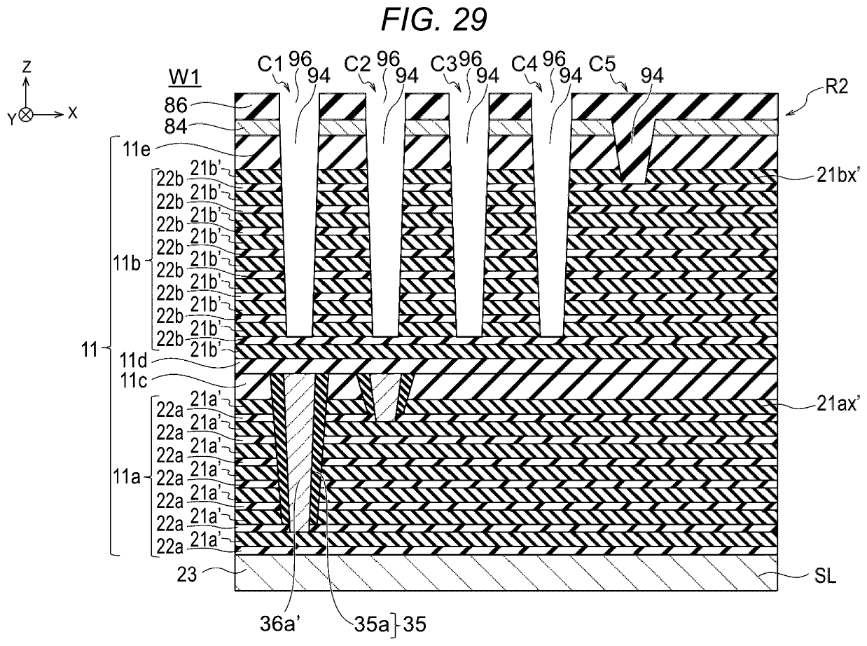

Next, after the resist layer 85 is removed, the resist layer 86 is formed on the hard mask layer 84 (FIG. 29). As a result, the recess portions 94 for the plugs C1 to C5 are filled with the resist layer 86.

Next, the resist layer 86 and the stacked film 11b are etched by lithography and RIE (FIG. 29). As a result, a plurality of recess portions 96 are formed in the resist layer 86, the resist layer 86 is removed from the recess portions 94 for the plugs C1 to C4, and the stacked film 11b in these recess portions 94 is further etched. Meanwhile, the resist layer 86 is left in the recess portion 94 for the plug C5. The etching of the stacked film 11b in FIG. 29 is performed such that the bottom surfaces of the recess portions 94 for the plugs C1 to C4 reach the upper surface of the predetermined insulating film 22b. Since the bottom surface of the recess portion 94 for the plug C5 reaches the upper surface of the predetermined insulating film 22b in the step shown in FIG. 28, the recess portion 94 for the plug C5 is not etched in the step shown in FIG. 29.

In the step shown in FIG. 29, etching for processing the recess portions 94 for the plugs C1 to C4 may be performed simultaneously or sequentially. When the recess portions 94 for the plugs C1 to C5 are etched in the step shown in FIG. 29, etching processes for processing the recess portions 94 for the plugs C1 to C5 may be performed simultaneously or sequentially in the step shown in FIG. 29. For example, etching processes for processing the recess portions 94 for the plugs C1 to C4 may be performed simultaneously, and etching for processing the recess portions 94 for the plugs C1 to C4 and etching for processing the recess portions 94 for the plug C5 may be performed sequentially. In this case, etching for processing the recess portions 94 for the plugs C1 to C4 and etching for processing the recess portions 94 for the plugs C5 are performed using, for example, separate resist layers 86.

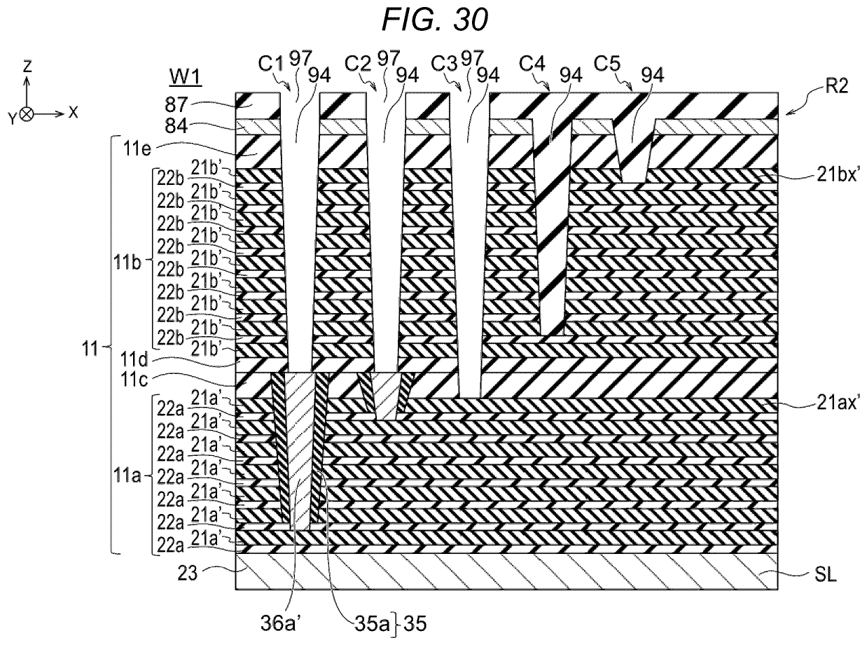

Next, after the resist layer 86 is removed, the resist layer 87 is formed on the hard mask layer 84 (FIG. 30). As a result, the recess portions 94 for the plugs C1 to C5 are filled with the resist layer 87.

Next, the resist layer 87, the stacked film 11b, the insulating film 11d, and the insulating film 11c are etched by lithography and RIE (FIG. 30). As a result, a plurality of recess portions 97 are formed in the resist layer 87, the resist layer 87 is removed from the recess portions 94 for the plugs C1 to C3, and the stacked film 11b and the insulating film 11d in the recess portions 94 for the plugs C1 and C2 and the stacked film 11b, the insulating film 11d, and the insulating film 11c in the recess portions 94 for the plugs C3 are further etched. Meanwhile, the resist layer 87 is left in the recess portions 94 for the plugs C4 and C5. The etching of the stacked film 11b, the insulating film 11d, and the insulating film 11c in FIG. 30 is performed such that the bottom surfaces of the recess portions 94 for the plugs C1 and C2 reach the upper surface of the corresponding sacrifice layer 36a′, and the bottom surface of the recess portion 94 for the plug C3 reaches the upper surface of the sacrifice layer 21ax′.

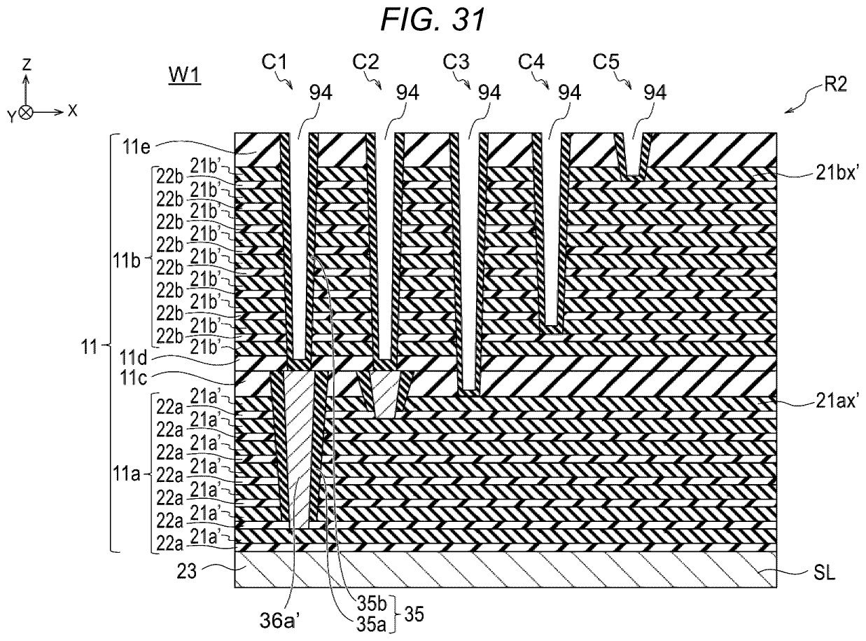

Next, after the resist layer 87 and the hard mask layer 84 are removed, the insulating film 35b of the spacer insulating film 35 is formed in each recess portion 94 (FIG. 31). As a result, the insulating film 35b is formed on the side surface and bottom surface of each recess portion 94.

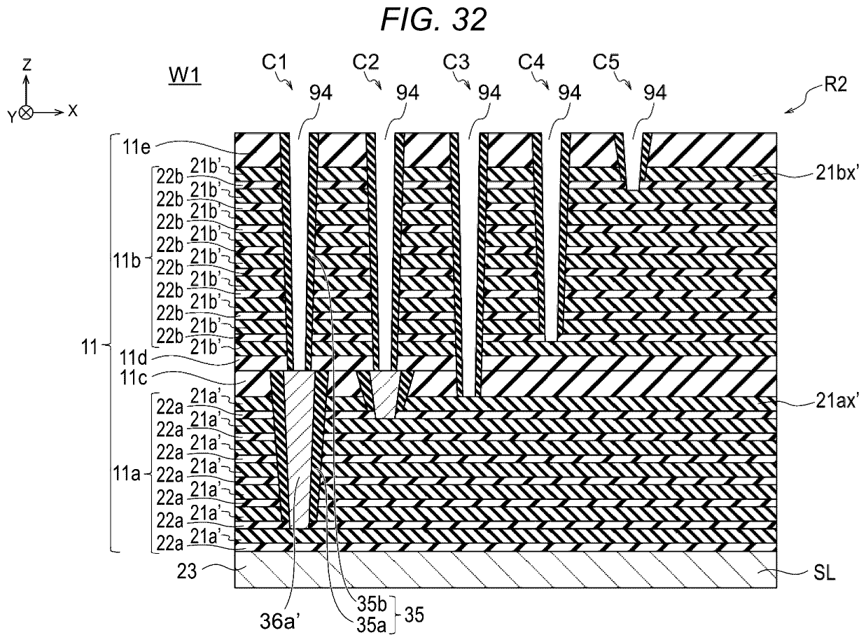

Next, the insulating film 35b is removed from the bottom surface of each recess portion 94 by lithography and RIE (FIG. 32). At this time, one insulating film 22b is further removed from the bottom surface of the recess portion 94 for the plug C4, and one insulating film 22b is further removed from the bottom surface of the recess portion 94 for the plug C5. As a result, the bottom surfaces of the recess portions 94 for the plugs C4 and C5 reach the upper surface of the predetermined sacrifice layer 21b′.

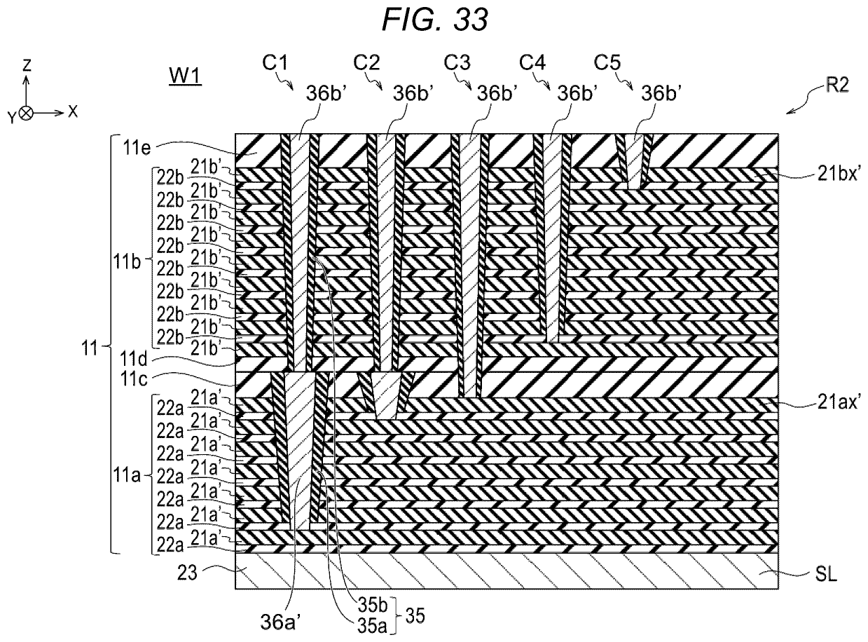

Next, the sacrifice layer 36b′ is embedded in each recess portion 94 (FIG. 33). As a result, the sacrifice layer 36b′ is formed on a predetermined sacrifice layer 36a′, sacrifice layer 21a′, or sacrifice layer 21b′ in each recess portion 94. The sacrifice layer 36b′ for the plugs C1 and C2 is an example of a second film. The sacrifice layer 36b′ for the plug C3 is an example of a third film. The sacrifice layer 36b′ for the plugs C4 and C5 is an example of a fourth film.

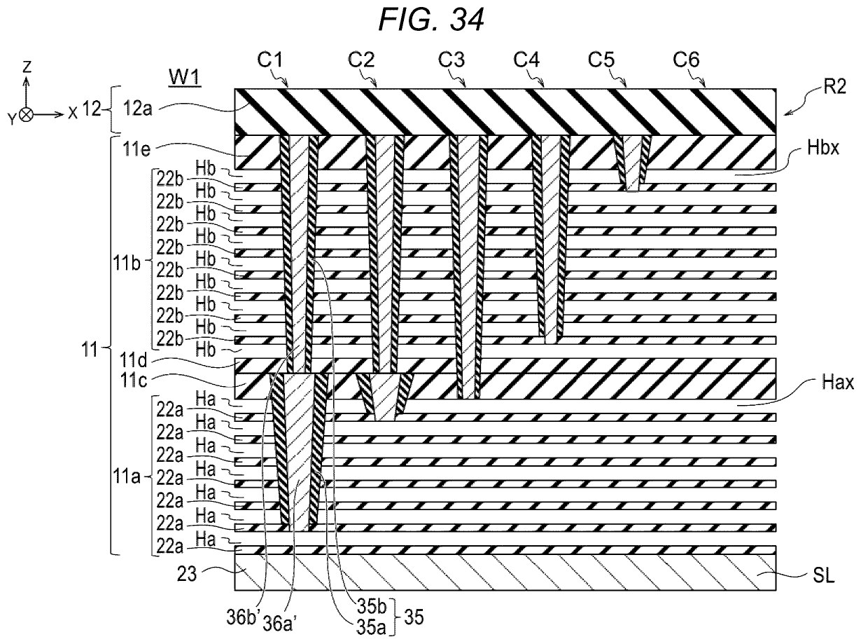

Next, the insulating film 12a for the interlayer insulating film 12 is formed on the insulating film 11e, the insulating film 35b, and the sacrifice layer 36b′ (FIG. 34). Next, a plurality of slits (not shown) penetrating the insulating film 12a, the insulating film 11e, the stacked film 11b, the insulating film 11d, the insulating film 11c, and the stacked film 11a are formed, and the sacrifice layers 21a′ and 21b′ are removed from the stacked films 11a and 11b by wet etching through these slits (FIG. 34). As a result, a plurality of recess portions Ha are formed in the stacked film 11a, and a plurality of recess portions Hb are formed in the stacked film 11b. The recess portion Hax shown in FIG. 34 is the uppermost recess portion Ha among the plurality of recess portions Ha of the stacked film 11a. The recess portion Hbx shown in FIG. 34 is the uppermost recess portion Hb among the plurality of recess portions Hb of the stacked film 11b.

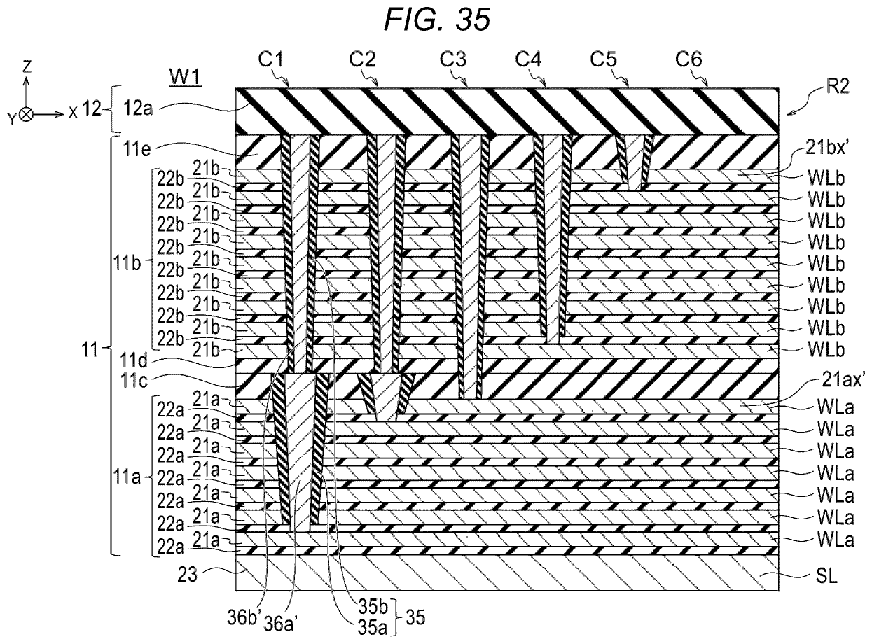

Next, the electrode layers 21a and 21b corresponding to the word lines WLa and WLb are formed in the recess portions Ha and Hb from the above-mentioned slits (FIG. 35). In this manner, the sacrifice layers 21a′ and 21b′ are replaced by the electrode layers 21a and 21b, respectively, to form the stacked film 11 including the electrode layers 21a and 21b. The electrode layer 21ax shown in FIG. 35 is the uppermost electrode layer 21a among the plurality of electrode layers 21a in the stacked film 11a. The electrode layer 21bx shown in FIG. 35 is the uppermost electrode layer 21b among the plurality of electrode layers 21b of the stacked film 11b.

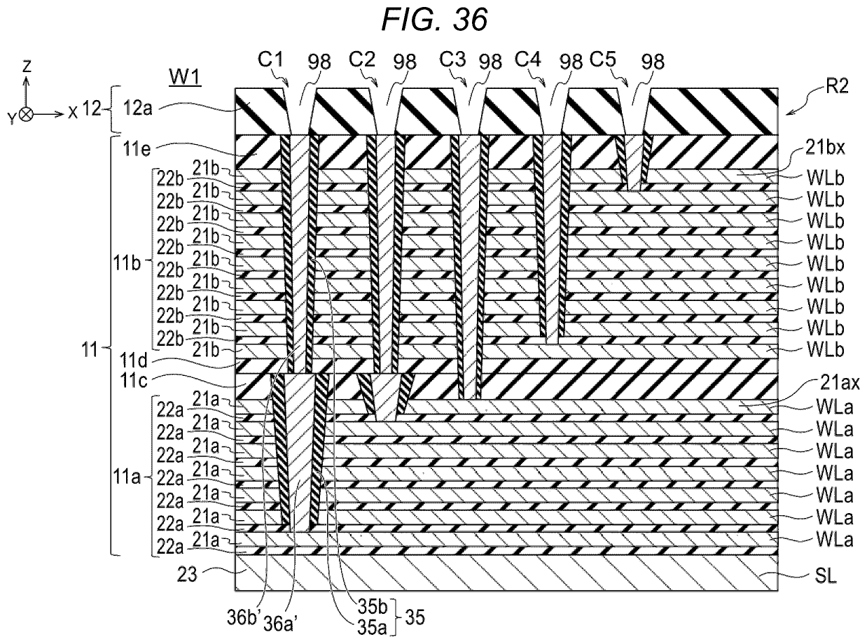

Next, the insulating film 12a is etched by RIE (FIG. 36). As a result, a plurality of recess portions 98 are formed in the insulating film 12a. These recess portions 98 are formed to be used as contact holes in which the contact plugs 37 of the plugs C1 to C5 are embedded. The etching of the insulating film 12a in FIG. 36 is performed such that the bottom surfaces of the recess portions 98 for the plugs C1 to C5 reach the upper surface of the corresponding sacrifice layer 36b′.

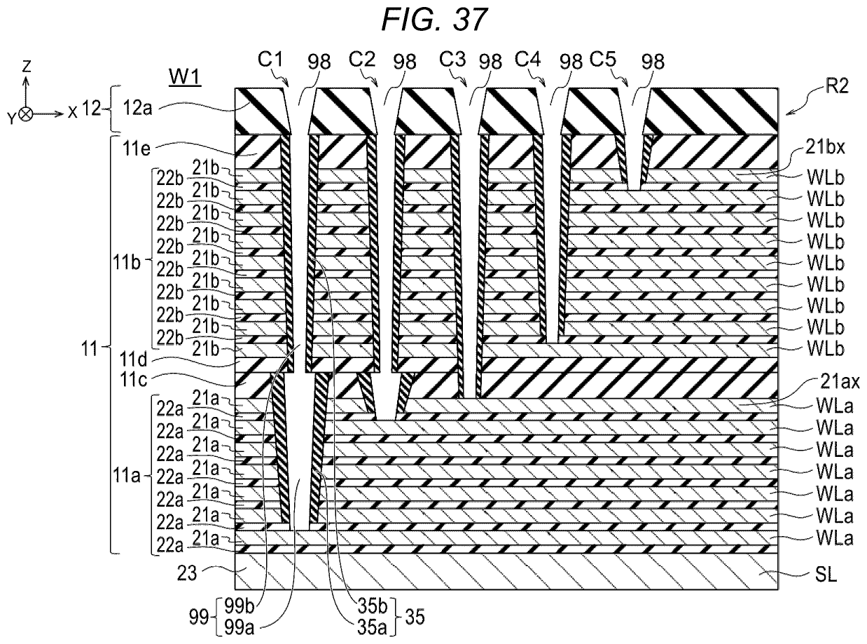

Next, the sacrifice layers 36a′ and 36b′ for the plugs C1 to C5 are removed from the stacked film 11 by etching from the recess portions 98 (FIG. 37). As a result, the recess portions 99 for the plugs C1 to C5 are formed in the stacked film 11. These recess portions 99 are formed to be used as contact holes in which the contact plugs 36 of the plugs C1 to C5 are embedded. Each of the recess portions 99 for the plugs C1 and C2 includes a recess portion 99a corresponding to the recess portion 91 and a recess portion 99b corresponding to the recess portion 94. On the other hand, each of the recess portions 99 for the plugs C3 to C5 includes only a recess portion 99b corresponding to the recess portion 94.

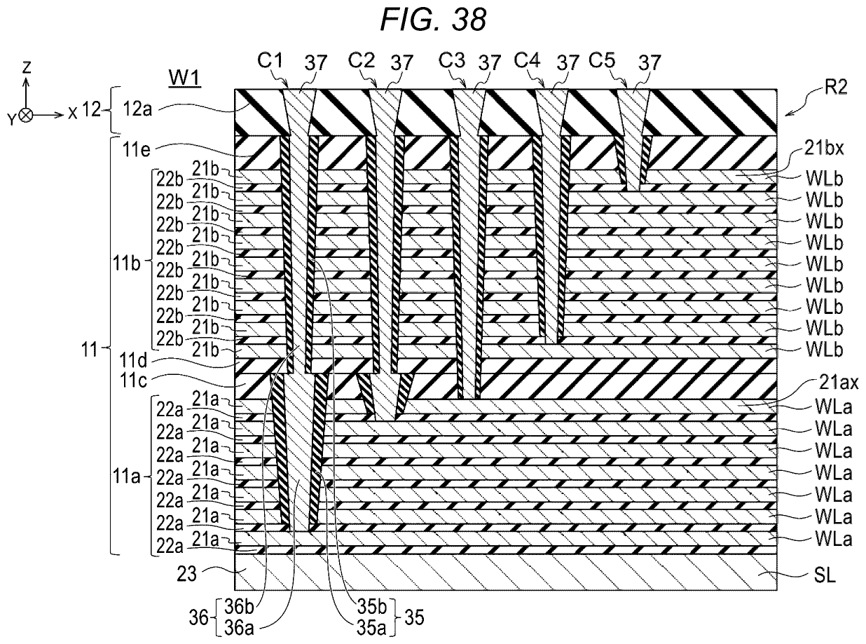

Next, material layers for the contact plugs 36 and 37 are embedded in the recess portions 98 and 99 for the plugs C1 to C5 (FIG. 38). As a result, the contact plugs 37 and 36 are formed in the recess portions 98 and 99, respectively. Specifically, the plugs 36a and 36b are formed in the recess portions 99a and 99b, respectively. Each of the plugs C1 to C3 is formed on the corresponding electrode layer 21a, and each of the plugs C4 to C6 is formed on the corresponding electrode layer 21b.

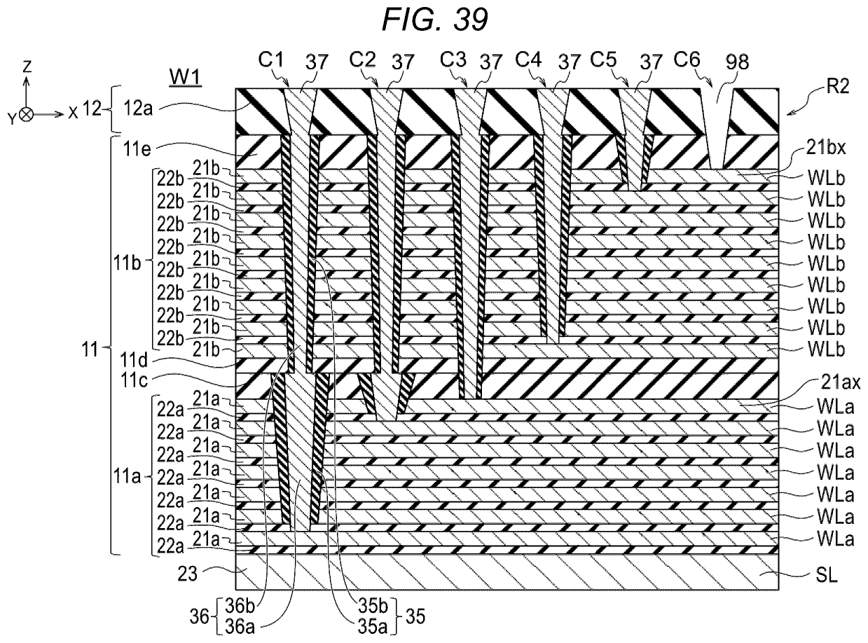

Next, the insulating film 12a and the insulating film 11e are etched by RIE (FIG. 39). As a result, the recess portion 98 is formed in the insulating film 12a and the insulating film 11e. The recess portion 98 is formed to be used as a contact hole in which the contact plug 37 of the plug C6 is embedded. The etching of the insulating film 12a and the insulating film 11e in FIG. 39 is performed such that the bottom surface of this recess portion 98 reaches the upper surface of the electrode layer 21bx.

The RIE in the step shown in FIG. 39 may be performed simultaneously with the RIE in the step shown in FIG. 36. Thereby, it is possible to form the recess portion 98 for the plug C6 simultaneously with the recess portions 98 for the plugs C1 to C5.

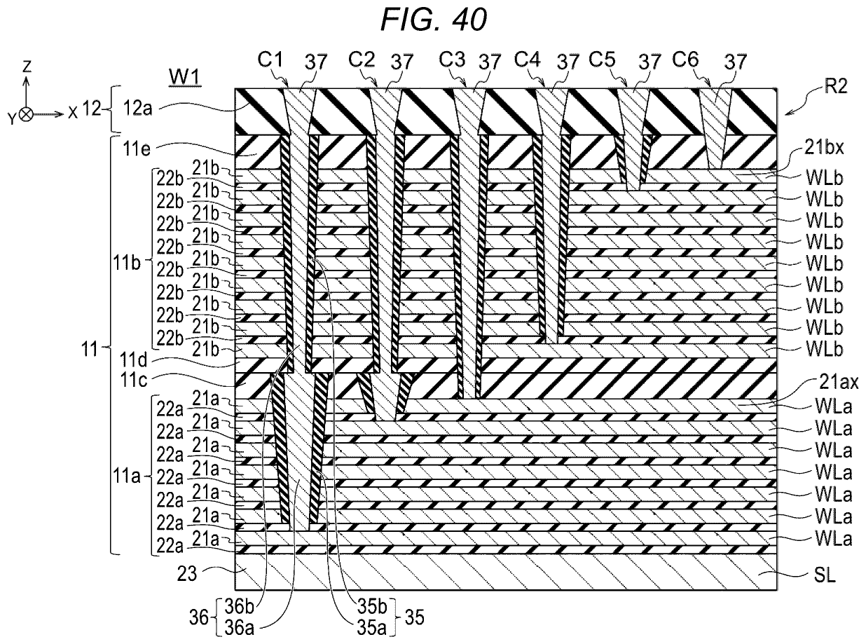

Next, a material layer for the contact plug 37 is embedded in the recess portion 98 for the plug C6 (FIG. 40). As a result, the plug C6 corresponding to contact plug 37 is formed in the recess portion 98 for the plug C6. The plug C6 is formed on the electrode layer 21bx. The material layer used in the step shown in FIG. 40 is, for example, the same as the material layer used in the step shown in FIG. 38. In this manner, the structure shown in FIG. 8 is formed.

The filling in the step shown in FIG. 40 may be performed simultaneously with the filling in the step shown in FIG. 38. For example, the steps (RIE) shown in FIGS. 36 and 39 may be performed simultaneously, then the step (etching) shown in FIG. 37 may be performed, and then the step or filling shown in FIGS. 38 and 40 may be performed simultaneously. Thereby, it is possible to form the plug C6 simultaneously with the plugs C1 to C5.

As described above, in the comparative example, when the semiconductor device is manufactured, it is difficult to preferably form the plugs C1 to C6 due to the insulating films 11c, 11d, 11e, 12a, 22a, 22b, and the like. For example, it is difficult to leave the insulating film 11c having a film thickness substantially the same as the film thickness of the insulating film 22a under each recess portion 91 in the step shown in FIG. 7 and to leave the insulating film 11e having a film thickness substantially the same as the film thickness of the insulating film 22b under each recess portion 94 in the step shown in FIG. 12. On the other hand, according to this embodiment, it is possible to avoid leaving the insulating films 11c and 11e under the recess portions 91 and 94 by forming the plug C3 without using the recess portion 91 and by forming the plug C6 without using the recess portion 94. Thereby, it is possible to preferably form the recess portions 91 and 94 for the plugs C1 to C6 by a simple process.

As described above, according to this embodiment, the plugs C1 to C6 can be preferably formed by forming the plug C3 without using the plug 36a and by forming the plug C6 without using the plug 36b. In this embodiment, the plug C3 is formed without using the plug 36a, and thus the diameter of the plug C3 changes continuously between the portion Pa and the portion Pb as shown in FIG. 6. Similarly, in this embodiment, the plug C6 is formed without using the plug 36b, and thus the diameter of the plug C6 changes continuously between the portion Pb and the portion Pc as shown in FIG. 6.

The hard mask layers 81 and 84 (see FIGS. 23, 28, and the like) in this embodiment are, for example, polysilicon layers. According to this embodiment, the hard mask layers 81 and 84 are formed as polysilicon layers, and thus it is possible to curb the transmission of exposure light through the hard mask layers 81 and 84 when the resist layers 82, 83, 85, 86, and 87 are exposed for lithography. The resist layers 82, 83, 85, 86, and 87 are formed of, for example, a negative resist material.

### Second Embodiment

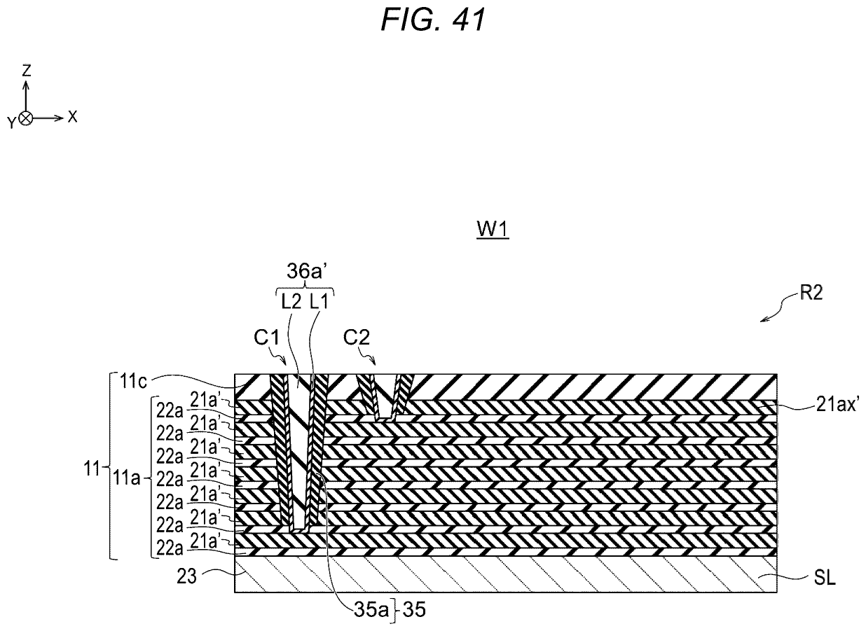

FIGS. 41 to 44 are cross-sectional views showing a method of manufacturing a semiconductor device according to a second embodiment. The method of manufacturing the semiconductor device according to this embodiment is generally the same as the method of manufacturing the semiconductor device according to the first embodiment, except for the following points.

FIG. 41 shows a step corresponding to the step shown in FIG. 27. A sacrifice layer 36a′ according to the second embodiment is formed by sequentially embedding sacrifice layers L1 and L2 in each recess portion 91. The sacrifice layer L2 is, for example, a SiN film. The sacrifice layer L1 is, for example, a protective film for protecting the SiN film. The sacrifice layer L2 may be a polysilicon layer, similar to the sacrifice layer 36a′ in the first embodiment.

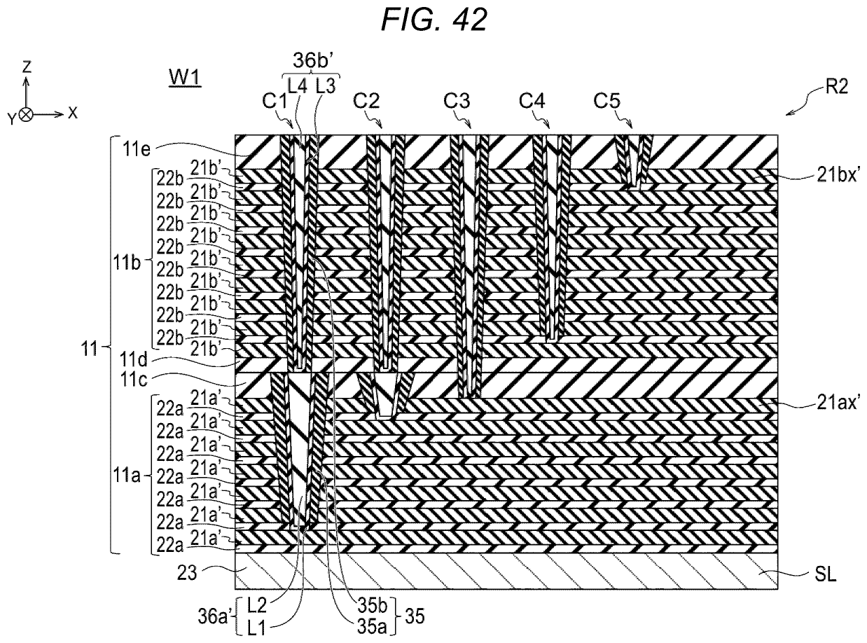

FIG. 42 shows a step corresponding to the step shown in FIG. 33. A sacrifice layer 36b′ according to the second embodiment is formed by sequentially embedding sacrifice layers L3 and L4 in each recess portion 94. The sacrifice layer L4 is, for example, a SiN film. The sacrifice layer L3 is, for example, a protective film for protecting the SiN film. The sacrifice layer L4 may be a polysilicon layer, similar to the sacrifice layer 36b′ in the first embodiment.

According to the second embodiment, the sacrifice layers L2 and L4 can be protected from an etching solution by the sacrifice layers L1 and L3 during wet etching shown in FIG. 34.

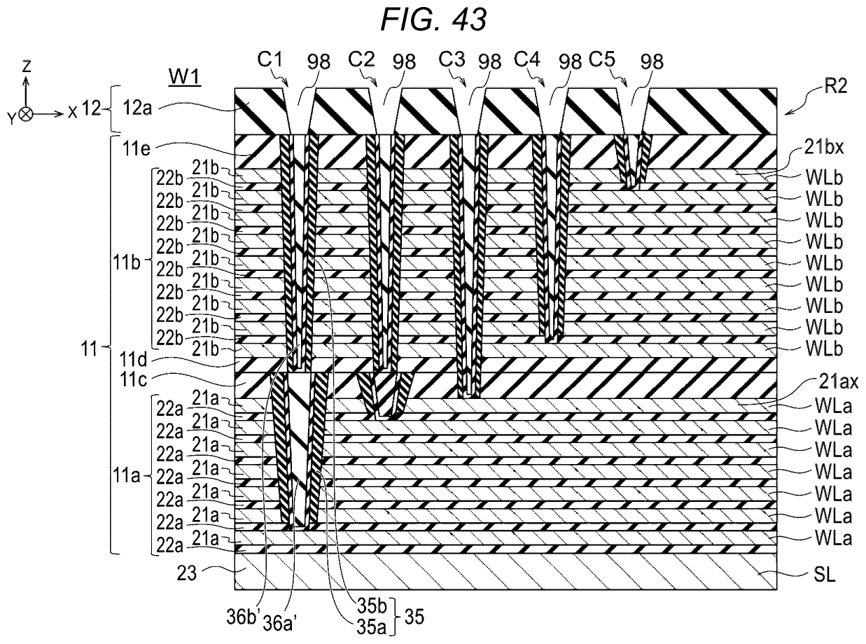

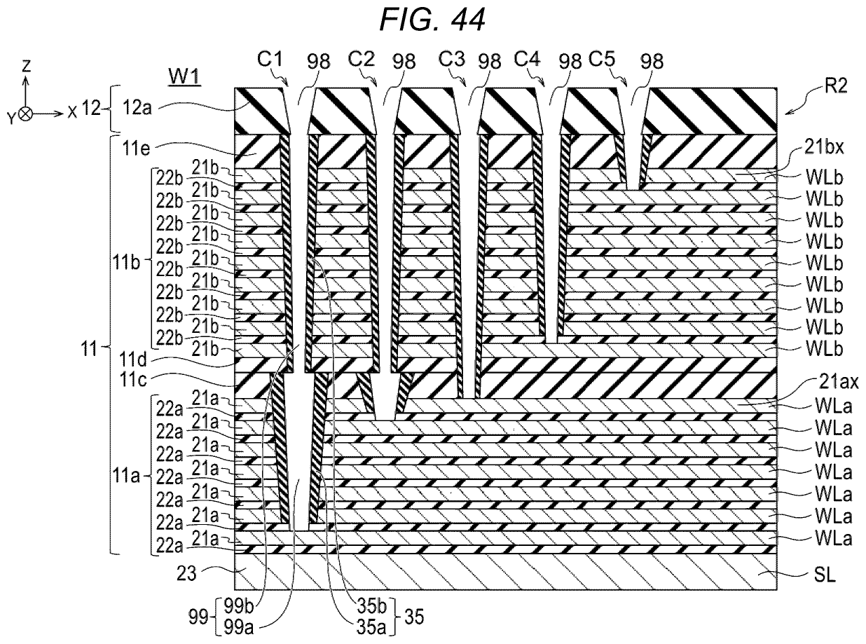

FIGS. 43 and 44 show steps corresponding to the steps shown in FIGS. 36 and 37. The sacrifice layers 36a′ and 36b′ (L1 to L4) in this embodiment are removed by etching from a recess portion 98, similar to the sacrifice layers 36a′ and 36b′ in the first embodiment.

According to the second embodiment, various materials can be used as the sacrifice layers L2 and L4 by using the sacrifice layers L1 and L3 functioning as protective films.

### Third Embodiment

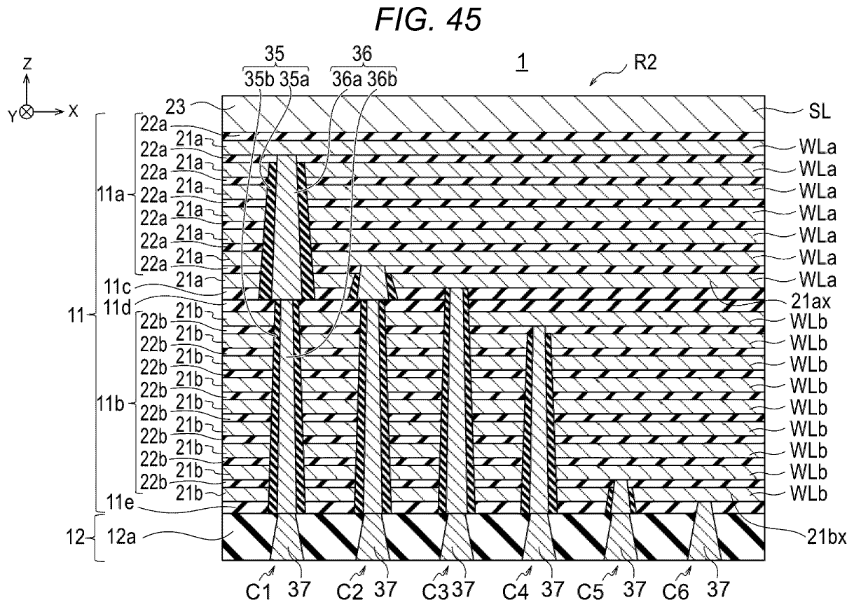

FIG. 45 is a cross-sectional view showing the structure of a semiconductor device according to a third embodiment.

The semiconductor device according to this embodiment (FIG. 45) has the same structure as that of the semiconductor device according to the first embodiment (FIG. 6). Thus, the semiconductor device according to the third embodiment can be manufactured, for example, by the method of manufacturing the semiconductor device according to the first embodiment shown in FIGS. 23 to 40.

However, the film thickness of an insulating film 11c in the third embodiment is set to be smaller than the film thickness of the insulating film 11c in the first embodiment. The insulating film 11c in the third embodiment is obtained, for example, by thinning the insulating film 11c between the step of FIG. 27 and the step of FIG. 28. The thinning of the insulating film 11c can be performed, for example, by CMP or dry etch-back. The film thickness of the insulating film 11c shown in FIG. 45 is, for example, the same as the film thicknesses of insulating films 22a and 22b. On the other hand, in this embodiment, the total film thickness (i.e., the film thickness of a joint insulating film) of the insulating films 11c and 11d shown in FIG. 45 may be set to be the same as the film thicknesses of the insulating films 22a and 22b.

Similarly, the film thickness of an insulating film 11e in this embodiment is set to be smaller than the film thickness of the insulating film 11e in the first embodiment. The insulating film 11e in the third embodiment is obtained, for example, by thinning the insulating film 11e between the step of FIG. 33 and the step of FIG. 34. The thinning of the insulating film 11e can be performed, for example, by CMP or dry etch-back. The film thickness of the insulating film 11e shown in FIG. 45 is, for example, the same as the film thicknesses of the insulating films 22a and 22b.

Thinning the film thicknesses of the insulating films 11c and 11e shown in FIG. 45 leads to an advantage that, for example, the film thickness of a stacked film 11 can be reduced. On the other hand, thickening the film thickness of the insulating films 11c and 11e shown in FIG. 45 leads to an advantage that, for example, a breakdown voltage of the semiconductor device according to this embodiment can be increased.

### Fourth Embodiment

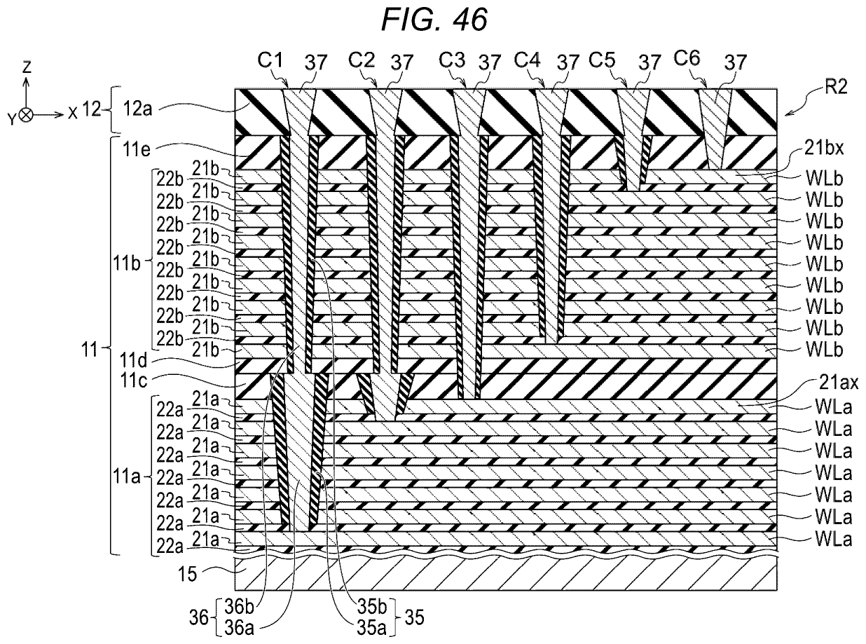

FIG. 46 is a cross-sectional view showing the structure of a semiconductor device according to a fourth embodiment.

The semiconductor device according to the first embodiment is manufactured by bonding the array wafer W1 and the circuit wafer W2 together as shown in FIGS. 3 and 4. On the other hand, the semiconductor device according to the fourth embodiment is manufactured without performing such bonding.

For this reason, as shown in FIG. 46, the semiconductor device according to this embodiment includes a substrate 15 that is removed during the manufacture of the semiconductor device in the first embodiment. The orientation of a stacked film 11 shown in FIG. 46 is opposite to the orientation of the stacked film 11 shown in FIGS. 1 and 6. This is because the stacked film 11 shown in FIG. 46 is drawn such that the substrate 15 is located below the stacked film 11, whereas the stacked film 11 shown in FIGS. 1 and 6 is drawn such that the substrate 14 is located below the stacked film 11. The stacked film 11 in the fourth embodiment has the same structure as that of the stacked film 11 in the first embodiment when the orientation shown in FIG. 46 is reversed.

### Fifth Embodiment

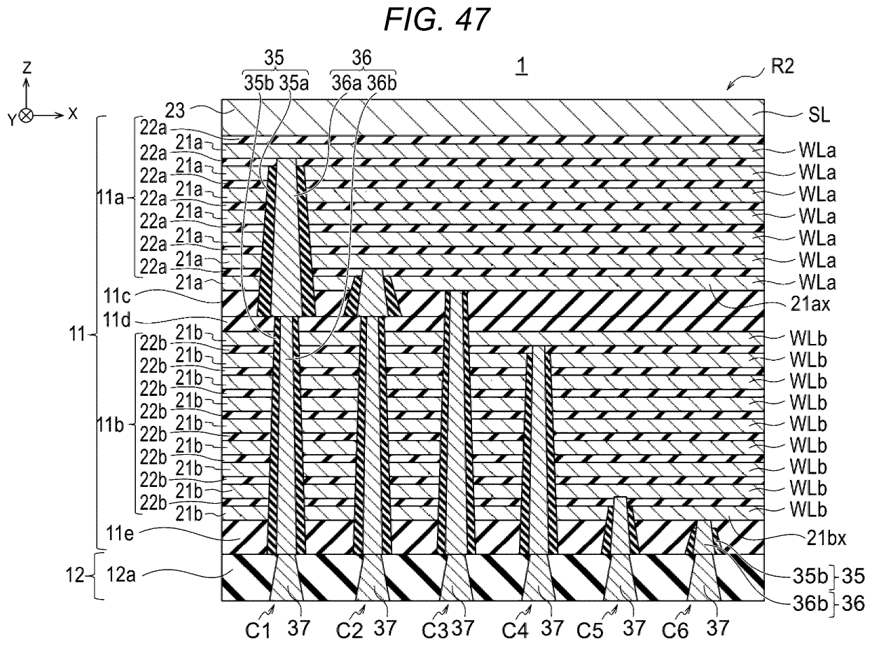

FIG. 47 is a cross-sectional view showing the structure of a semiconductor device according to a fifth embodiment.

The semiconductor device according to this embodiment (FIG. 47) has the same structure as that of the semiconductor device according to the first embodiment (FIG. 6). However, a plug C3 in the fifth embodiment has the same structure as that of the plug C3 shown in FIG. 6, while a plug C6 in this embodiment has the same structure as that of the plug C6 shown in FIG. 5.

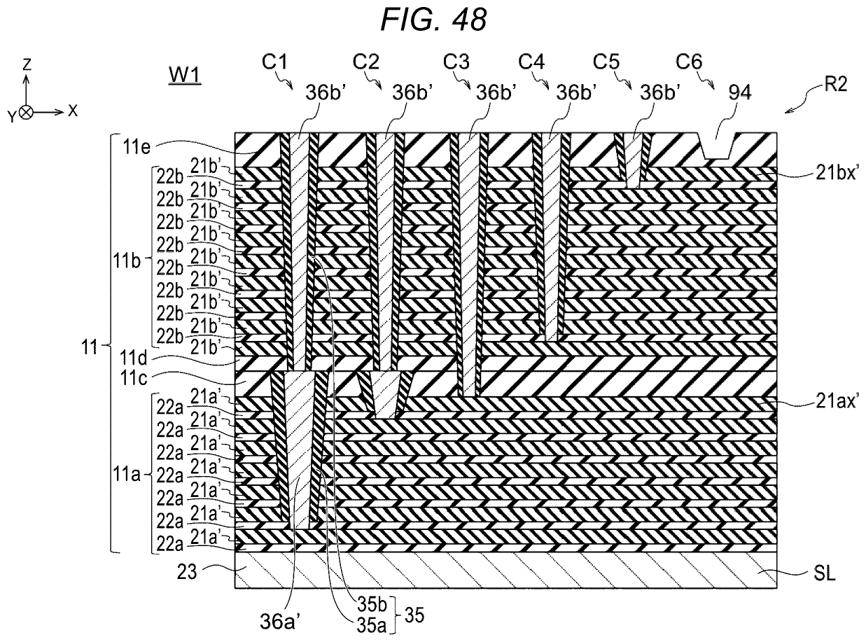

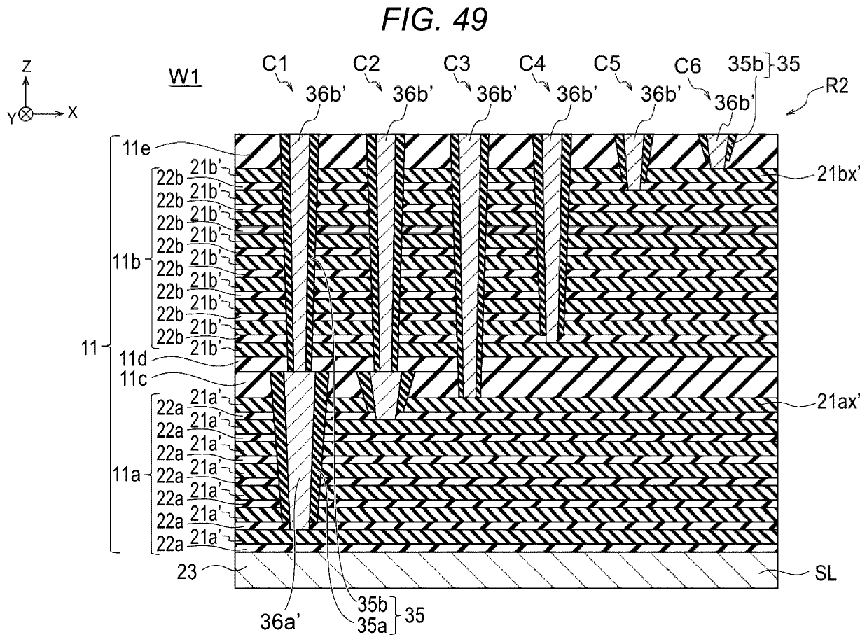

FIGS. 48 and 49 are cross-sectional views showing a method of manufacturing the semiconductor device according to the fifth embodiment.

The semiconductor device according to this embodiment is manufactured by the method of manufacturing the semiconductor device according to the first embodiment shown in FIGS. 23 to 40. However, in the fifth embodiment, steps of FIGS. 48 and 49 are performed between the step of FIG. 33 and the step of FIG. 34. In the steps of FIGS. 48 and 49, an insulating film 35b and a sacrifice layer 36b′ for the plug C6 are formed in the same flow as that of the steps of FIGS. 12 to 17. Furthermore, in this embodiment, steps of FIGS. 36 to 38 are performed not only on plugs C1 to C5 but also on the plug C6, and steps of FIG. 39 and FIG. 40 are omitted.

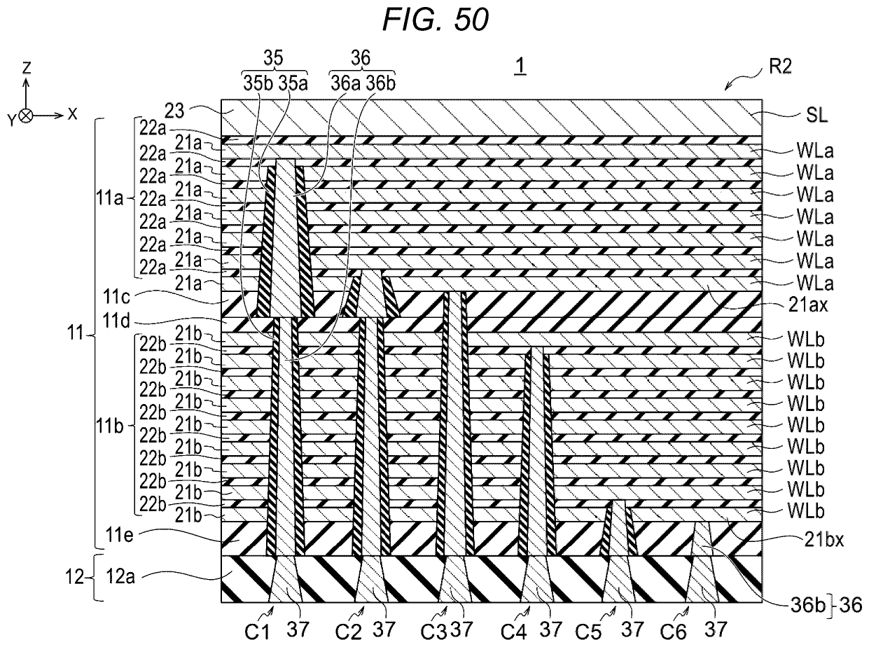

FIG. 50 is a cross-sectional view showing the structure of a semiconductor device according to a modification example of the fifth embodiment.

The semiconductor device according to this modification example (FIG. 50) has a structure similar to that of the semiconductor device according to the fifth embodiment (FIG. 47). However, the side surface of a plug 36b in a plug C6 according to this modification example is not surrounded by an insulating film 35b. Since the plug 36b is not formed in a stacked film 11b, the step of forming the insulating film 35b for the plug 36b can be omitted.

As described above, according to this embodiment, the same structure as that in the first embodiment can be adopted for only the plug C3 out of the plugs C3 and C6.

### Sixth Embodiment

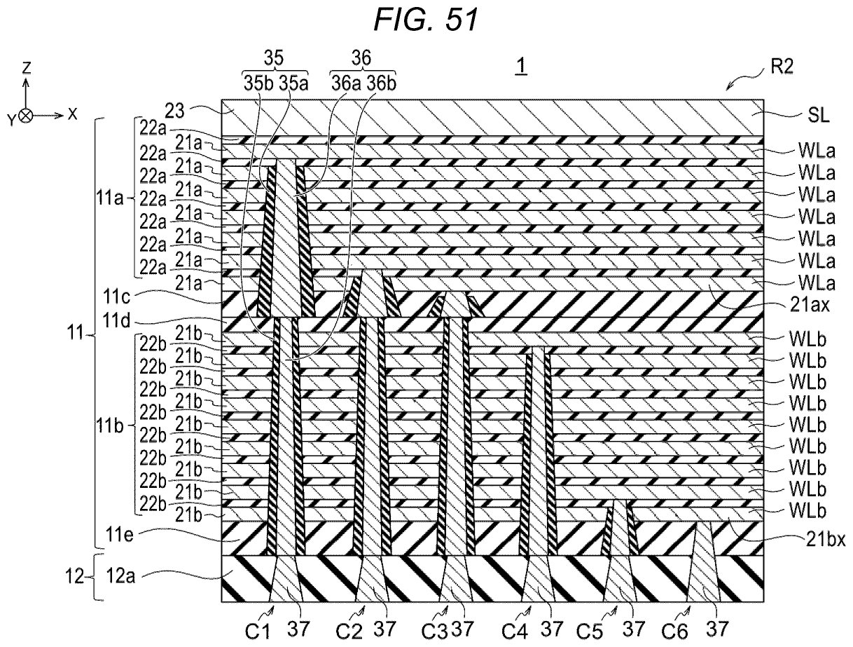

FIG. 51 is a cross-sectional view showing the structure of a semiconductor device according to a sixth embodiment.

The semiconductor device according to this embodiment (FIG. 51) has a structure similar to that of the semiconductor device according to the first embodiment (FIG. 6). However, a plug C6 in the sixth embodiment has the same structure as that of the plug C6 shown in FIG. 6, whereas a plug C3 in this embodiment has the same structure as that of the plug C3 shown in FIG. 5.

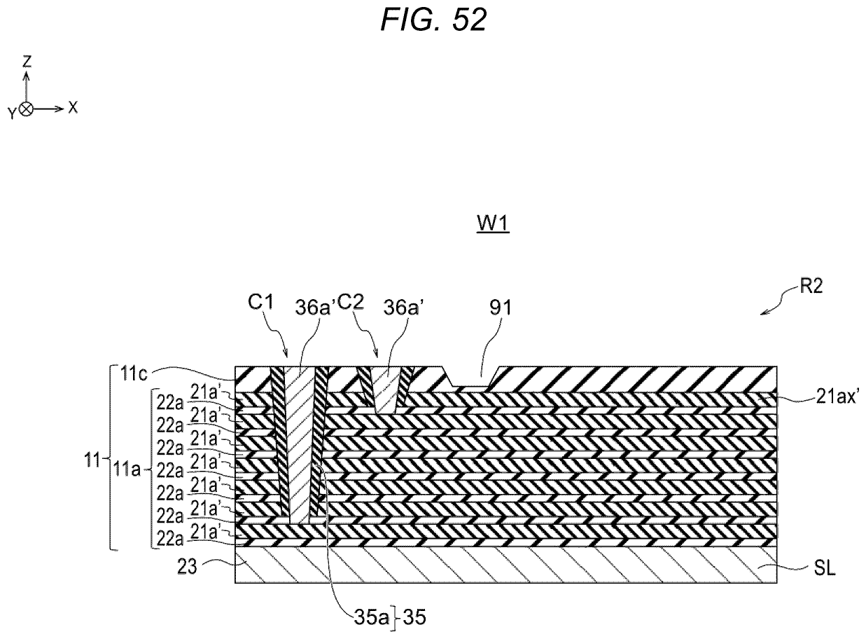

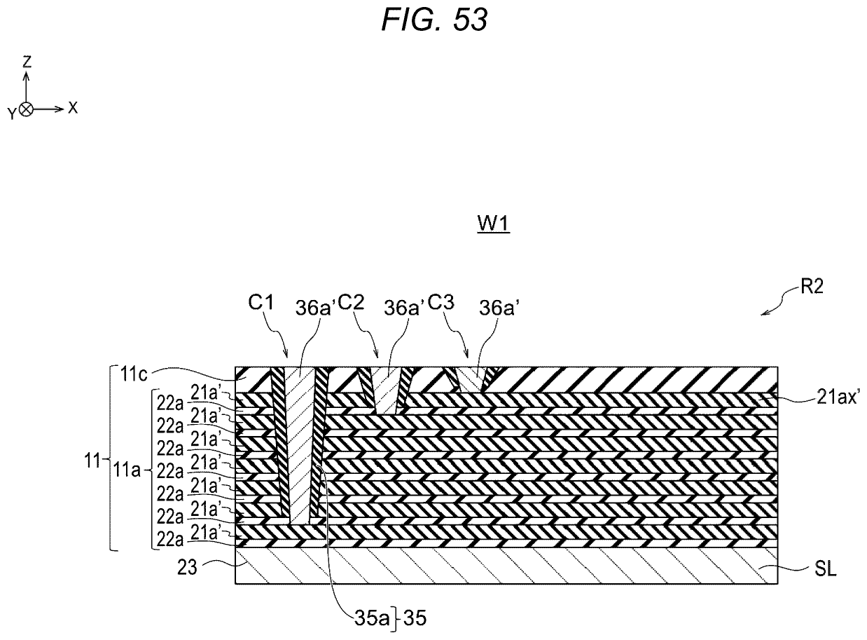

FIGS. 52 and 53 are cross-sectional views showing a method of manufacturing the semiconductor device according to the sixth embodiment.

The semiconductor device according to this embodiment is manufactured by the method of manufacturing the semiconductor device according to the first embodiment shown in FIGS. 23 to 40. However, in the sixth embodiment, steps of FIGS. 52 and 53 are performed between the step of FIG. 27 and the step of FIG. 28. In the steps of FIGS. 52 and 53, an insulating film 35a and a sacrifice layer 36a′ for a plug C3 are formed in the same flow as that of the steps of FIGS. 7 to 11. Furthermore, in this embodiment, in the step of FIG. 30, a recess portion 94 for the plug C3 is processed in the same manner as recess portions 94 for plugs C1 and C2.

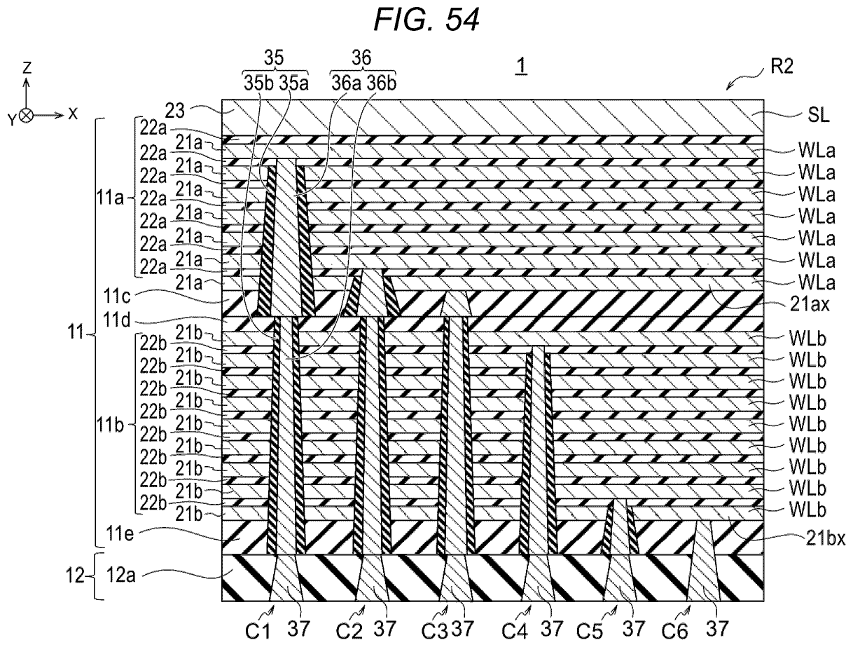

FIG. 54 is a cross-sectional view showing the structure of a semiconductor device according to a modification example of the sixth embodiment.

The semiconductor device of this modification example (FIG. 54) has a structure similar to that of the semiconductor device according to the sixth embodiment (FIG. 51). However, the side surface of a plug 36a in a plug C3 in this modification example is not surrounded by an insulating film 35a. Since the plug 36a is not formed in a stacked film 11a, the step of forming the insulating film 35a for the plug 36a can be omitted.

As described above, according to this embodiment, the same structure as that in the first embodiment can be adopted for only the plug C6 out of the plugs C3 and C6.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first insulating film;
a second insulating film on the first insulating film;
a first electrode layer on the second insulating film;
a plurality of second electrode layers above the first electrode layer and spaced apart from each other in a first direction;
a third insulating film on each of the first electrode layer and the plurality of second electrode layers;
a fourth insulating film on the third insulating film;
a third electrode layer on the fourth insulating film;
a plurality of fourth electrode layers above the third electrode layer and spaced apart from each other in the first direction;
a first plug extending in the first direction and electrically connected to the first electrode layer;
a second plug extending in the first direction and electrically connected to any one of the second electrode layers;
a third plug extending in the first direction and electrically connected to the third electrode layer; and
a fourth plug extending in the first direction and electrically connected to any one of the fourth electrode layers, wherein
the fourth plug includes:
a first portion penetrating the second insulating film, the first electrode layer, the second electrode layers, and the third insulating film, and
a second portion disposed on the first portion and penetrating the fourth insulating film and the third electrode layer,
a diameter of the fourth plug changes discontinuously along the first direction at a boundary between the first and second portions,
the third plug includes:
a third portion penetrating the second insulating film, the first electrode layer, the second electrode layers, and the third insulating film, and
a fourth portion disposed on the third portion and penetrating the fourth insulating film, and
a diameter of the third plug changes discontinuously along the first direction at a boundary between the third and fourth portions.

2. The semiconductor device according to claim 1, wherein
the second plug includes a fifth portion penetrating the first insulating film and a sixth portion disposed on the fifth portion and penetrating the second insulating film and the first electrode layer,
a diameter of the second plug changes discontinuously along the first direction at a boundary between the fifth and sixth portions,
the first plug includes a seventh portion penetrating the first insulating film and an eighth portion disposed on the seventh portion and penetrating the second insulating film, and
a diameter of the first plug changes continuously along the first direction at a boundary between the seventh and eighth portions.

3. The semiconductor device according to claim 2, wherein
only the sixth portion among the fifth to eighth portions is surrounded by an insulating film having a tubular shape extending in the first direction.

4. The semiconductor device according to claim 2, wherein
the first direction is a direction from the first electrode layer towards the third electrode layer, and
a diameter of each of the fifth to eighth portions decreases in the first direction.

5. The semiconductor device according to claim 1, wherein
the fourth plug further includes a ninth portion disposed below the first portion and penetrating the first insulating film,
a diameter of the fourth plug changes discontinuously along the first direction at a boundary between the first and ninth portions,
the third plug further includes a tenth portion disposed below the third portion and penetrating the first insulating film, and
a diameter of the third plug changes discontinuously along the first direction at a boundary between the third and tenth portions.

6. The semiconductor device according to claim 1, wherein
each of the first to fourth portions is surrounded by an insulating film having a tubular shape extending in the first direction.

7. The semiconductor device according to claim 1, wherein
the first direction is a direction from the first electrode layer towards the third electrode layer, and
a diameter of each of the first to fourth portions decreases in the first direction.

8. The semiconductor device according to claim 1, further comprising:
a plurality of fifth insulating films disposed on the first electrode layer and arranged alternately with the second electrode layers in the first direction, and
a total film thickness of the third and fourth insulating films is larger than a film thickness of at least one of the fifth insulating films.

9. The semiconductor device according to claim 1, further comprising:
a plurality of sixth insulating films disposed on the third electrode layer and arranged alternately with the fourth electrode layers in the first direction, and
a total film thickness of the third and fourth insulating films is larger than a film thickness of at least one of the sixth insulating films.

10. A semiconductor device comprising:
a first insulating film;
a second insulating film on the first insulating film;
a first electrode layer on the second insulating film;
a plurality of second electrode layers above the first electrode layer and spaced apart from each other in a first direction;
a third insulating film on each of the first electrode layer and the plurality of second electrode layers;
a fourth insulating film on the third insulating film;
a third electrode layer on the fourth insulating film;
a plurality of fourth electrode layers above the third electrode layer and spaced apart from each other in the first direction;
a first plug extending in the first direction and electrically connected to the first electrode layer;
a second plug extending in the first direction and electrically connected to any one of the second electrode layers;
a third plug extending in the first direction and electrically connected to the third electrode layer; and
a fourth plug extending in the first direction and electrically connected to any one of the fourth electrode layers, wherein
the second plug includes:
a fifth portion penetrating the first insulating film and
a sixth portion disposed on the fifth portion and penetrating the second insulating film,
a diameter of the second plug changes discontinuously along the first direction at a boundary between the fifth and sixth portions,
the first plug includes:
a seventh portion penetrating the first insulating film and
an eighth portion disposed on the seventh portion and penetrating the second insulating film, and
a diameter of the first plug changes discontinuously along the first direction at a boundary between the seventh and eighth portions.

11. The semiconductor device according to claim 10, wherein
the fourth plug includes:
a first portion penetrating the second insulating film, the first electrode layer, the second electrode layers, and the third insulating film, and
a second portion on the first portion and penetrating the fourth insulating film and the third electrode layer,
a diameter of the fourth plug changes discontinuously along the first direction at a boundary between the first and second portions,
the third plug includes:
a third portion penetrating the second insulating film, the first electrode layer, the second electrode layers, and the third insulating film, and
a fourth portion disposed on the third portion and penetrating the fourth insulating film, and
a diameter of the third plug changes continuously along the first direction at a boundary between the third and fourth portions.

12. The semiconductor device according to claim 11, wherein
each of the first to fourth portions is surrounded by an insulating film having a tubular shape extending in the first direction.

13. The semiconductor device according to claim 11, wherein
the first direction is a direction from the first electrode layer towards the third electrode layer, and
a diameter of each of the first to fourth portions decreases in the first direction.

14. The semiconductor device according to claim 10, wherein
only the sixth portion among the fifth to eighth portions is surrounded by an insulating film having a tubular shape extending in the first direction.

15. The semiconductor device according to claim 10, wherein
the first direction is a direction from the first electrode layer towards the third electrode layer, and
a diameter of each of the fifth to eighth portions decreases in the first direction.

16. The semiconductor device according to claim 10, further comprising:
a plurality of fifth insulating films disposed on the first electrode layer and arranged alternately with the second electrode layers in the first direction, and
a total film thickness of the third and fourth insulating films is larger than a film thickness of at least one of the fifth insulating films.

17. The semiconductor device according to claim 10, further comprising:
a plurality of sixth insulating films disposed on the third electrode layer and arranged alternately with the fourth electrode layers in the first direction, and
a total film thickness of the third and fourth insulating films is larger than a film thickness of at least one of the sixth insulating films.

18. A method of manufacturing a semiconductor device, the method comprising:
forming a plurality of fourth layers spaced apart from each other in a first direction and forming a third layer above the plurality of fourth layers;
forming a fourth insulating film on the third layer;
forming a first hole to reach any one of the fourth layers and forming a first film in the first hole;
forming a third insulating film on the fourth insulating film after forming the first film;
forming a plurality of second layers spaced apart from each other in the first direction on the third insulating film and forming a first layer above the plurality of second layers;
forming a second insulating film on the first layer;
forming a second hole to reach the first film and forming a second film in the second hole;
forming a third hole to reach the third layer and forming a third film in the third hole;
replacing the first to fourth layers with first to fourth electrode layers;
removing the first and second films to form a fourth recess portion;
forming a fourth plug on any one of the fourth electrode layers in the fourth recess portion;
removing the third film to form a third recess portion; and
forming a third plug on the third electrode layer in the third recess portion.

19. The method according to claim 18, further comprising:
forming a first insulating film on the second insulating film after forming the second and third films, wherein
the fourth recess portion is formed by etching the first insulating film and removing the first and second films, and
the third recess portion is formed by etching the first insulating film and removing the third film.

20. A method of manufacturing a semiconductor device, the method comprising:
forming a plurality of fourth layers spaced apart from each other in a first direction and forming a third layer above the plurality of fourth layers;
forming a fourth insulating film on the third layer;
forming a third insulating film on the fourth insulating film;
forming a plurality of second layers spaced apart from each other in the first direction on the third insulating film and forming a first layer above the plurality of second layers;
forming a second insulating film on the first layer;
forming a first hole to reach any one of the second layers and forming a fourth film in the first hole;
replacing the first to fourth layers with first to fourth electrode layers;
forming a first insulating film on the second insulating film after forming the fourth film;
etching the first insulating film and removing the fourth film to form a second recess portion;
forming a second plug on any one of the second electrode layers in the second recess portion;
etching the first and second insulating films to form a first recess portion; and
forming a first plug on the first electrode layer in the first recess portion.
